(19) United States
(12) Patent Application Publication
(10) Pub. No.: US 2022/0283244 A1
(43) Pub. Date: Sep. 8, 2022

(54) BATTERY MONITORING DEVICE

(71) Applicant: DENSO CORPORATION, Kariya-city (JP)

(72) Inventors: Kazutaka HONDA, Kariya-city (JP); Akira KAWAMOTO, Kariya-city (JP); Tatsuki HYODOU, Kariya-city (JP)

(21) Appl. No.: 17/825,649

(22) Filed: May 26, 2022

Related U.S. Application Data
(63) Continuation of application No. PCT/JP2020/041885, filed on Nov. 10, 2020.

(30) Foreign Application Priority Data
Dec. 4, 2019 (JP) 2019-219572
Apr. 30, 2020 (JP) 2020-080318

(51) Int. Cl. G01R 31/396; H02J 7/00; G01R 31/3835; H01M 10/48; H01M 10/44; H01M 10/42

(52) U.S. Cl. CPC G01R 31/396; H02J 7/0016; H02J 7/0048; G01R 31/3835; H01M 10/482; H01M 10/441; H01M 10/4257; H01M 2010/4271

(57) ABSTRACT

A battery monitoring device includes multiple A/D converters, a digital filter, an anti-alias filter, and a detection controller. The multiple A/D converters are provided in correspondence with multiple battery cells in an assemble battery. Each of the A/D converters is configured to receive an input voltage according to a voltage of corresponding one of the battery cells. The digital filter is configured to receive a digital signal output from each of the A/D converters and function as a low-pass filter. The anti-alias filter is configured to suppress aliasing by the digital filter. The detection controller is configured to control operation of the A/D converters so that the input voltage input to each of the A/D converters is A/D converted at a same timing, and detect the voltage of each of the battery cells based on an output signal of the digital filter.

### CROSS REFERENCE TO RELATED APPLICATIONS

The present application is a continuation application of International Patent Application No. PCT/JP2020/041885 filed on Nov. 10, 2020, which designated the U.S. and claims the benefit of priority from Japanese Patent Application No. 2019-219572 filed on Dec. 4, 2019 and Japanese Patent Application No. 2020-080318 filed on Apr. 30, 2020. The entire disclosures of all of the above applications are incorporated herein by reference.

### TECHNICAL FIELD

The present disclosure relates to a battery monitoring device.

### BACKGROUND

There has been known a battery monitoring device that monitors an assembled battery in which multiple battery cells are connected in series.

SUMMARY The present disclosure provides a battery monitoring device including multiple analog-to-digital (A/D) converters, a digital filter, an anti-alias filter, and a detection controller. The multiple A/D converters are provided in correspondence with multiple battery cells in an assemble battery. Each of the A/D converters is configured to receive an input voltage according to a voltage of corresponding one of the battery cells. The digital filter is configured to receive a digital signal output from each of the A/D converters and function as a low-pass filter. The anti-alias filter is configured to suppress aliasing by the digital filter. The detection controller is configured to control operation of the A/D converters so that the input voltage input to each of the A/D converters is A/D converted at a same timing, and detect the voltage of each of the battery cells based on an output signal of the digital filter.

### BRIEF DESCRIPTION OF DRAWINGS

Objects, features and advantages of the present disclosure will become apparent from the following detailed description made with reference to the accompanying drawings. In the drawings:

FIG. 1 is a diagram schematically illustrating a configuration of a system using a battery monitoring unit according to a first embodiment;

FIG. 2 is a diagram schematically illustrating an equivalent circuit of a battery cell according to the first embodiment;

FIG. 3A is a diagram schematically illustrating a waveform of a current of the battery cell according to the first embodiment;

FIG. 3B is a diagram schematically illustrating a waveforms of a voltage of the battery cell according to the first embodiment;

FIG. 4 is a diagram schematically illustrating a state where variations occur in the capacity of battery cells according to the first embodiment;

FIG. 5 is a diagram illustrating a relation between the number of battery modules mounted in a vehicle and the kinds of vehicles according to the first embodiment;

FIG. 6 is a diagram schematically illustrating a configuration related to communication in an integral-type configuration according to the first embodiment;

FIG. 7 is a diagram schematically illustrating a configuration related to communication in a distributed-type configuration according to the first embodiment;

FIG. 8 is a diagram for explaining outline of communication between a microcomputer and a battery monitoring device according to the first embodiment;

FIG. 9 is a diagram schematically illustrating a specific general configuration of the battery monitoring device according to the first embodiment;

FIG. 10 is a diagram illustrating operation states of components in each operation mode of the battery monitoring device according to the first embodiment;

FIG. 11 is a diagram schematically illustrating a specific circuit configuration of the battery monitoring device according to the first embodiment;

FIG. 12 is a diagram schematically illustrating characteristics of an entire filter exerting an influence on a result of detection of the voltage of the battery cell according to the first embodiment;

FIG. 13 is a diagram schematically illustrating a specific configuration of an A/D converter according to the first embodiment;

FIG. 14 is a diagram schematically illustrating a specific chip configuration of the battery monitoring device according to the first embodiment;

FIG. 15 is a diagram schematically illustrating a specific configuration of a digital filter according to the first embodiment;

FIG. 16 is a diagram schematically illustrating a specific configuration of a comb-shaped filter according to the first embodiment;

FIG. 17 is a diagram schematically illustrating a specific configuration of an A/D converter according to a second embodiment;

FIG. 18 is a diagram schematically illustrating a specific circuit configuration of a battery monitoring device according to a third embodiment;

FIG. 19 is a diagram schematically illustrating voltage detection timings and noise superimposed on battery cells according to the third embodiment;

FIG. 20 is a diagram schematically illustrating voltage detection timings and noise superimposed on battery cells according to a comparison example of the third embodiment;

FIG. 21 is a diagram schematically illustrating voltage detection timings and noise superimposed on battery cells according to a modification of the third embodiment;

FIG. 22 is a diagram schematically illustrating a specific circuit configuration of a battery monitoring device according to a fourth embodiment;

FIG. 23 is a diagram schematically illustrating a system configuration including a battery monitoring device according to a comparison example of the fourth embodiment;

FIG. 24 is a timing chart schematically illustrating waveforms of voltages at the time of equalization process according to the comparison example of the fourth embodiment; and

FIG. 25 is a timing chart schematically illustrating waveforms of voltages at the time of equalization process according to the first to fourth embodiments.

### DETAILED DESCRIPTION

A battery monitoring device includes a multiplexer and an A/D converter. The battery monitoring device is configured to A/D convert voltages of multiple battery cells in a time division manner by using the A/D converter and detect the voltages. In the present disclosure, the A/D converter will be also abbreviated as ADC. In the configuration of an all-cell-sharing ADC, it is difficult to realize excellent detection accuracy while making timings of detecting the voltages of the battery cells the same because of the following reason. There are various forms in ADCs and, in ADCs, conversion accuracy and conversion speed have a trade-off relation.

Consequently, in the case of employing an ADC in the form of high conversion speed as the ADC in the above configuration, timings of detecting voltages of battery cells can be made the same, that is, synchronousness of obtaining all of cells can be increased but the voltage detection accuracy is low. In the case of employing an ADC in the form of high conversion accuracy as the ADC in the above configuration, the accuracy of detecting voltages of battery cells is excellent but it is difficult to make the voltage detection timings the same, that is, the synchronousness of obtaining all of cells is low.

In another battery monitoring device, ADCs are provided for battery cells, respectively and the voltages of the battery cells are detected by the ADCs. According to this configuration, even in the case of using an ADC in the form of high conversion accuracy, improvement in the synchronousness of obtaining all of cells can be expected.

In the above configuration, in order to shift the level of the voltage of a battery cell having a relatively high common mode voltage to a voltage in an input range of an ADC, a differential amplifier circuit is provided at the stage before each ADC. In such a configuration, by regulating a bandwidth of a passing signal by an amplifier as a component of the differential amplifier circuit, a function equivalent to a configuration of inputting the voltage of a battery cell to the ADC via an RC filter, specifically, a function of eliminating cell noise as a noise superimposed on the battery cell is realized. Consequently, according to the above configuration, deterioration in the accuracy of detecting a voltage by cell noise can be suppressed. However, in this case, an offset error of the amplifier, a level-shift error due to resistance voltage division, or the like occurs, so that it is difficult to sufficiently increase the voltage detection accuracy.

A battery monitoring device according to an aspect of the present disclosure is for monitoring an assembled battery in which multiple battery cells are connected in series, and includes multiple A/D converters, a digital filter, an anti-alias filter, and a detection controller. The A/D converters are provided in correspondence with the multiple battery cells, respectively. Each of the A/D converters is configured to receive an input voltage according to a voltage of corresponding one of the battery cells. The digital filter is configured to receive a digital signal output from each of the A/D converters and function as a low-pass filter. The anti-alias filter is configured to suppress aliasing by the digital filter. The detection controller is configured to control operation of the A/D converters so that the input voltage input to each of the A/D converters is A/D converted at a same timing, and detect the voltage of each of the battery cells based on an output signal of the digital filter.

In the above configuration, the detection controller controls the operation of the A/D converters so that the input voltage input to each of the A/D converters is A/D converted at the same timing. It enables the detection controller to detect the voltage of each of battery cells based on the digital signal obtained by performing A/D conversion by the A/D converters at the same timing. Consequently, according to the above configuration, the timings of detecting the voltages of the battery cells can be made the same, that is, the synchronousness of the timings of detecting the voltages of the battery cells can be increased.

Further, in the above configuration, cell noise is eliminated by the digital filter. Generally, the aliasing occurs in the digital filter. However, in the above configuration, the anti-alias filter for suppressing occurrence of the aliasing is provided. As described above, in the above configuration, cell noise can be eliminated without providing a differential amplification circuit in the stage before each of A/D converters, so that the above-described various errors due to the differential amplification circuit do not occur. Therefore, according to the above configuration, excellent effects can be obtained such that synchronousness of timings of detecting voltages of battery cells is increased and accuracy of detecting voltages can be increased.

Hereinafter, multiple embodiments will be described with reference to the drawings. In the embodiments, the same reference numeral is designated to the substantially the same configurations, and repetitive description is omitted.

### First Embodiment

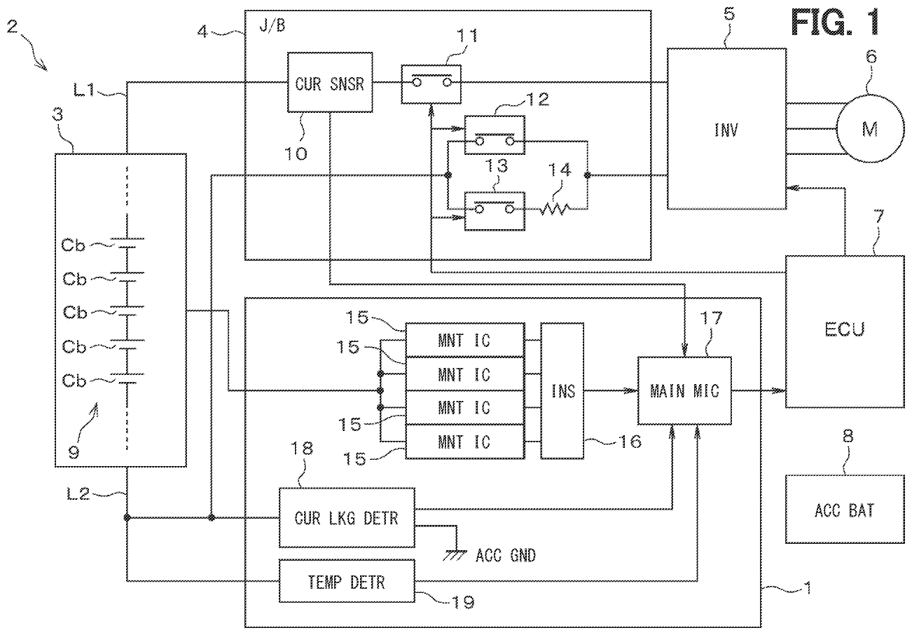

Hereinafter, a first embodiment will be described with reference to FIGS. 1 to 16.

### <General Configuration>

As illustrated in FIG. 1, a battery monitoring unit 1 of the present embodiment monitors a battery stack 3 used for a system 2 electrified in a vehicle. Vehicles to which the system 2 is applied include an HEV as a hybrid vehicle, a PHV as a plug-in hybrid vehicle, and an EV as an electric vehicle. The system 2 has, in addition to the above-described battery monitoring unit 1 and the battery stack 3, a junction box (J/B) 4, an inverter (INV) 5, a motor 6, an electronic control unit (ECU) 7, an accessory battery (ACC BAT) 8 and the like.

The battery stack 3 has a configuration that multiple battery cells Cb are connected in series between a pair of DC power lines L1 and L2. In the present embodiment, the battery cell Cb is configured by, for example, a secondary cell such as a lithium-ion battery. In FIG. 1, only a part of the multiple battery cells Cb is illustrated. Every predetermined number of the battery cells Cb are combined as one battery module 9. In other words, the battery module 9 is configured by the battery cells Cb as a part of the multiple battery cells Cb. The battery stack 3 is configured by the multiple battery modules 9 having such a configuration.

In this case, each battery module 9 corresponds to an assembled battery in which the multiple battery cells Cb are connected in series. Although not illustrated, the battery cells Cb and the battery modules 9 are connected electrically by a bus bar as a conductive member. In the above configuration, a common mode voltage is superimposed to the battery cells Cb. The common mode voltage becomes higher toward the upper-stage side of the battery module 9, that is, the battery cell Cb connected on the high-potential side, and its maximum value is a relatively high voltage such as, for example, a few hundred volts.

The DC power lines L1 and L2 are led into the J/B 4. In the J/B 4, various components related to connection and the like, specifically, a current sensor (CUR SNSR) 10, relays 11 to 13, a resistor 14, and the like are provided. The DC power line L1 on the high potential side is connected to the inverter 5 via the current sensor 10 and the relay 11. The DC power line L2 on the low potential side is connected to the inverter 5 via the relay 12. The DC power line L2 is also connected to the inverter 5 via the relay 13 and the resistor 14.

The relays 11 and 12 are system main relays and are always on when the system 2 executes normal operation. On the other hand, the relay 13 is a pre-charge relay and is turned on only for a predetermined period at the time of starting the system 2. Consequently, at the start of the system 2, the current for charging the input capacitor of the inverter 5 from the battery stack 3 is regulated by the resistor 14, and inrush current at the time of start is reduced. The current sensor 10 detects the currents flowing in the battery stack 3, that is, charge/discharge current to/from the battery cells Cb. A current detection signal output from the current sensor 10 is given to the battery monitoring unit 1.

The inverter 5 has a main circuit in which six semiconductor switching elements are connected in the form of a three-phase full bridge. As a semiconductor switching element, for example, a power MOSFET, an IGBT, or the like can be used. The inverter 5 converts, at the time of travel of the vehicle, DC power given from the battery stack 3 via the J/B 4 and a not-illustrated boost converter to AC power and supplies the AC power to the motor 6. The operation of the inverter 5 is controlled based on a command given from the ECU 7. In such a manner, the ECU 7 controls the driving of the motor 6, particularly, the torque generated by the motor 6 at the time of travel of the vehicle. At the time of braking of the vehicle, regenerative electric power regenerated from the motor 6 via the inverter 5 is supplied to the battery stack 3 via the J/B 4 and the like.

The ECU 7 controls overall operation of the system 2. Specifically, the ECU 7 performs detection of various abnormalities, various fail-safe controls, calculation of state of charge (SOC) of the battery cell Cb, calculation of a charge power upper limit value and a discharge power lower limit value of the battery cell Cb, calculation of a charge/discharge power request for the battery cell Cb, calculation of a control torque command corresponding to a command value of the torque generated by the motor 6, on-off control of the relays 11 to 13 of the J/B 4, control of a not-illustrated cooling fan for cooling the battery monitoring unit 1, and the like.

The accessory battery 8 supplies power to various electric components mounted in the vehicle including the above-described cooling fan. The accessory battery 8 can be charged by DC power supplied from the battery stack 3 via the J/B 4. In this case, the DC power supplied from the battery stack 3 is stepped down via a not-illustrated DC/DC converter and supplied to the accessory battery 8.

The battery monitoring unit 1 has multiple monitoring ICs (MNT IC) 15 as battery monitoring devices respectively provided for the multiple battery modules 9 of the battery stack 3, an insulating unit (INS) 16, a main microcomputer (MAIN MIC) 17, a current leakage detector (CUR LKG DETR) 18, a temperature detector (TEMP DETR) 19, and the like. To each of the monitoring IC 15, the terminal voltage of each of the battery cells Cb constructing the battery module 9 as an object of the monitoring is input.

Each of the monitoring ICs 15 executes a predetermined process for monitoring the corresponding battery module 9. The predetermined process executed by each of the monitoring ICs 15 includes a process of detecting the voltage of the battery cell Cb, a failure diagnosis as a diagnosis of disconnection, failure detection of a function block, or the like, a process of battery equalization for equalizing the voltages of the battery cells Cb, and the like.

Each of the monitoring ICs 15 performs communication conformed to a predetermined communication protocol with the main microcomputer 17. Via the communication, each of the monitoring ICs 15 receives data such as a command from the main microcomputer 17 and transmits data such as a detection result obtained by executing each process to the main microcomputer 17. In this case, a common mode voltage to be superimposed to the battery cell Cb is applied to each of the monitoring ICs 15. Due to this, each of the monitoring ICs 15 and the main microcomputer 17 are insulated from each other by the insulating unit 16 made by, for example, a photocoupler, a magnetic coupler, or the like.

The current leakage detector 18 detects current leakage of the battery stack 3 based on the potential of the DC power line L2 on the low potential side connected to the battery stack 3 and the ground for accessories. In FIG. 1, the ground for accessories is called accessary GND (ACC GND). The result of detection of current leakage by the current leakage detector 18 is given to the main microcomputer 17. Although not illustrated, in the battery stack 3, a temperature sensor such as a thermistor is provided near the battery cell Cb. To the temperature detector 19, a temperature detection signal output from such a temperature sensor is given. The temperature detector 19 detects the temperature of the battery cell Cb based on the temperature detection signal. The result of detection of temperature by the temperature detector 19 is given to the main microcomputer 17.

On the basis of each of detection results given as described above, the main microcomputer 17 executes various processes such as voltage detection of all of the battery cells Cb, detection of overcharge/overdischarge of the battery cell Cb, disconnection detection, and failure diagnosis. The main microcomputer 17 performs serial communication or the like with the ECU 7 and transmits/receives various data via the communication.

### <Functions Related to Battery Monitoring>

The functions related to the battery monitoring realized by the battery monitoring unit 1 are as follows.

### (1) Voltage Detection

In voltage detection, voltage between the terminals of each battery cell Cb is detected. The result of such voltage detection is used for SOC calculation which will be described later or the like. As accuracy of the voltage detection, high detection accuracy is required particularly at the time of overcharge detection and at the time of overdischarge detection.

### (2) SOC Calculation

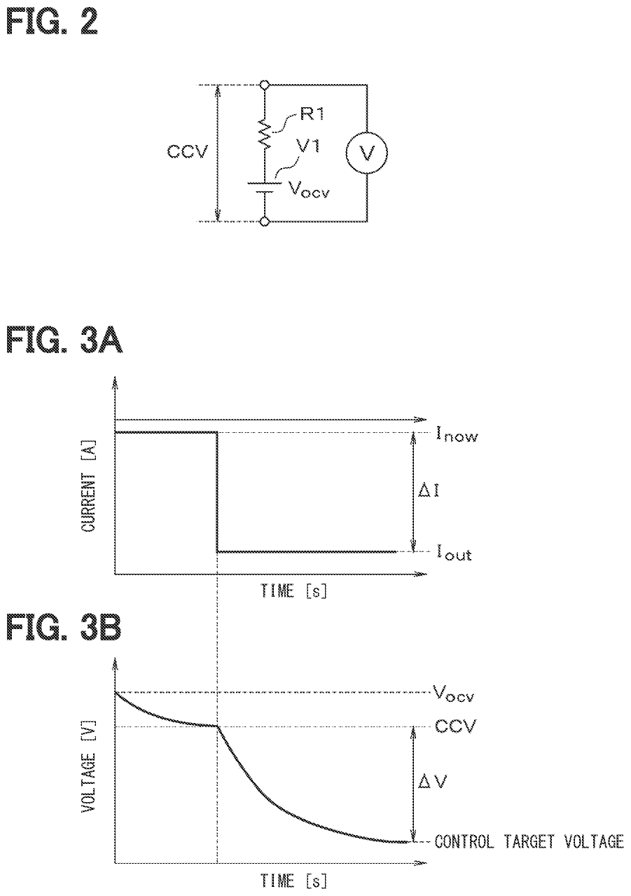

SOC has correlation with a value at the time when the battery cell Cb is open. When the battery cell Cb is used, an error due to the charge/discharge current to the battery cell Cb occurs. As illustrated in FIG. 2, equivalently, the battery cell Cb is expressed by a series circuit of an internal resistor R1 and a voltage source V1.

Consequently, as illustrated in FIGS. 3A and 3B, when current flows in the battery cell Cb, a cell voltage CCV as a voltage seen from the outside of the battery cell Cb decreases from a voltage V_{OCV} of the voltage source V1. In the above configuration, therefore, the voltage value and the current value of the battery cell Cb are monitored, and a true SOC is estimated based on the monitor results. Such calculation of the SOC is performed by the main microcomputer 17.

### (3) Temperature Detection

In the above configuration, cooling structure design which suppresses temperature variation of each battery cell Cb is performed. In temperature detection, temperatures at multiple representative places are sensed.

### (4) Failure Diagnosis

In the failure diagnosis, diagnosis of disconnection, sticking failure of a switch, failure detection of the function blocks such as the ADC, and the like are performed.

### (5) Battery Equalization

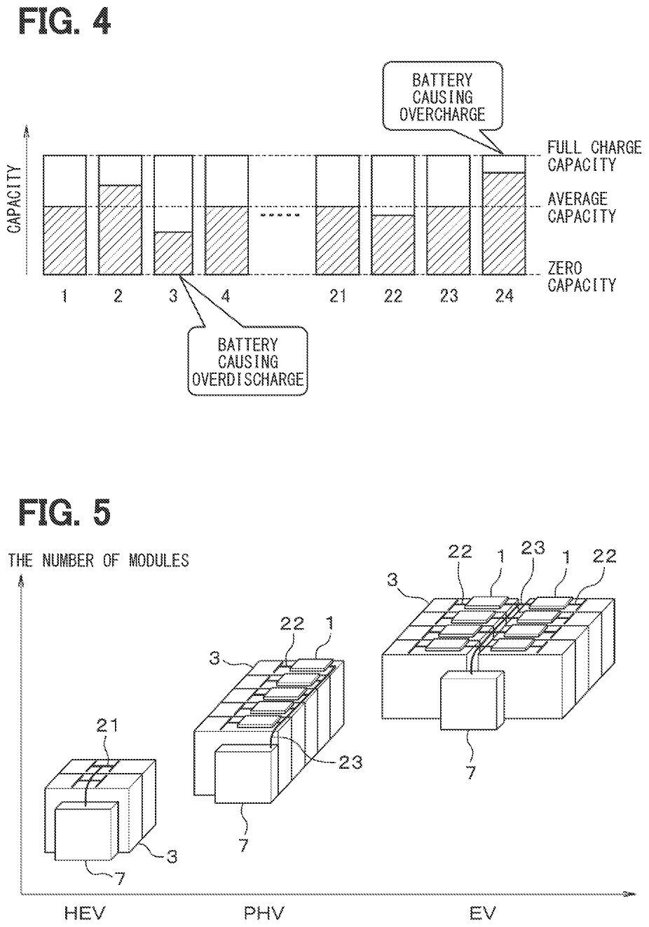

The battery equalization is a process of equalizing the voltages of the battery cells Cb. In this case, a discharge circuit made by a switch, a resistor, and the like is provided every battery cell Cb, and the operation of each discharge circuit is controlled so that the voltages of the battery cells Cb become a voltage which is almost equal to the lowest voltage of the battery cell Cb. As illustrated in FIG. 4, when the battery cell Cb causing overcharge or overdischarge appears due to variations in the capacity of the battery cells Cb, charging cannot be performed after that time point. In the above configuration, therefore, the battery equalization as described above is performed so that charging can be performed.

### <Specific Arrangement of Battery Monitoring Unit and ECU>

As illustrated in FIG. 5, the size of the battery pack mounted in the vehicle, that is, the above-described battery stack 3 tends to become larger in order of HEV, PHV, and EV and, similarly, the number of battery modules 9 also tends to increase.

In an HEV, for example, the configuration disclosed in JP 6160557 B2, that is, an integrated-type configuration in which the battery monitoring unit 1 having the function of monitoring the battery cells Cb is provided in the ECU 7 is employed. In this case, the battery stack 3 and the ECU 7 are connected by a voltage detection line 21 for detecting the voltage of the battery cells Cb. On the other hand, in a PHV and an EV, accompanying increase in the size of the battery stack 3, a distributed-type configuration that the battery monitoring unit 1 is disposed very close to the battery stack 3 independently of the ECU 7 is employed. In FIG. 5, reference numeral 1 is designated to only a part of multiple battery monitoring units.

In such a distributed-type configuration, a circuit board on which circuit elements constructing the battery monitoring unit 1 are mounted is mounted just above the battery stack 3, so that its miniaturization is strongly demanded. In the present disclosure, the battery monitoring unit 1 in such a configuration is also called an SBM. The SBM is abbreviation of Satellite Battery Monitor. In this case, the battery stack 3 and the battery monitoring unit 1 are connected by a voltage detection line 22.

In FIG. 5, reference numeral 22 is designated to only a part of multiple voltage detection lines. In this case, the battery monitoring unit 1 and the ECU 7 are connected via a communication line 23. By such a distributed-type configuration, since the voltage detection line is shortened as compared with the integrated-type configuration, effects are obtained such that a wire in the vehicle is reduced and the degree of freedom of mounting to a vehicle is improved.

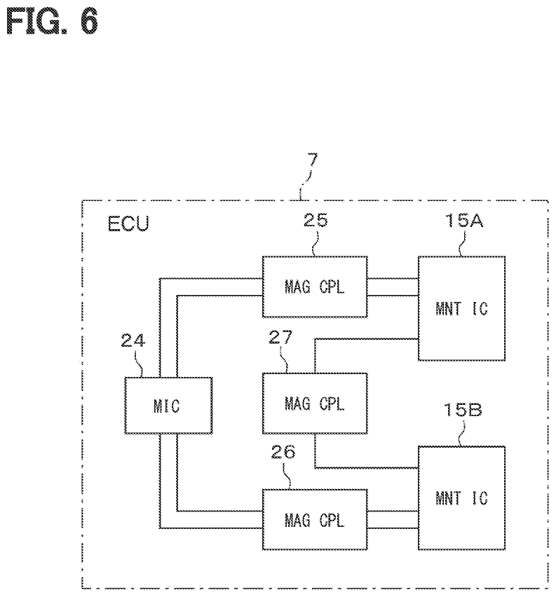

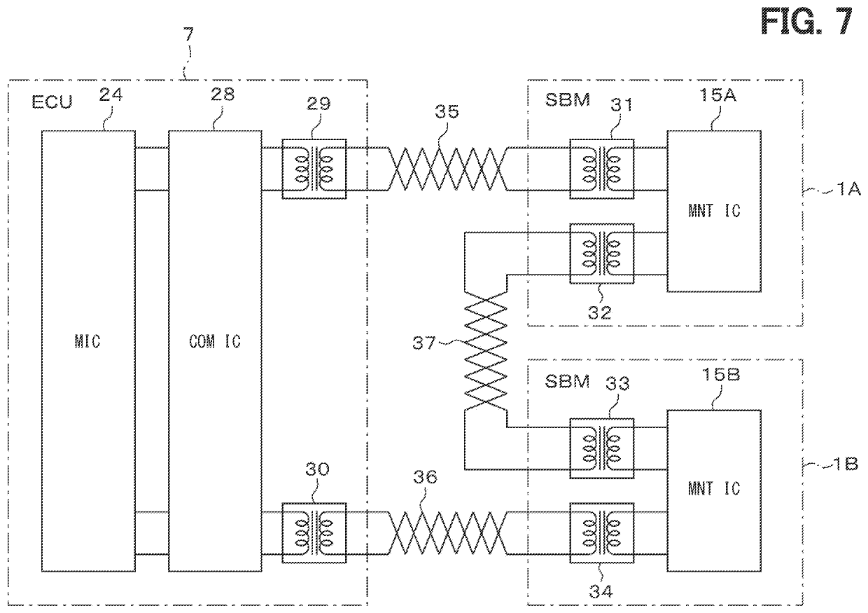

Subsequently, the configuration related to communication in each of the integrated-type configuration and the distributed-type configuration will be described with reference to FIGS. 6 and 7. In FIGS. 6 and 7, to simplify the description, it is assumed that the number of monitoring ICs 15 is two. “A” and “B” are designated to the two monitoring ICs 15 and components corresponding to the two monitoring ICs 15 so as to be discriminated.

As illustrated in FIG. 6, in the integrated-type configuration, the ECU 7 has a microcomputer (MIC) 24, magnetic couplers (MAG CPL) 25 to 27, and monitoring ICs (MNT IC) 15A and 15B. The microcomputer 24 and the monitoring IC 15A can perform communication via the magnetic coupler 25. The microcomputer 24 and the monitoring IC 15B can perform communication via the magnetic coupler 26. The monitoring ICs 15A and 15B can perform communication via the magnetic coupler 27.

As illustrated in FIG. 7, in the distributed-type configuration, the ECU 7 has the microcomputer 24, a communication IC (COM IC) 28, and pulse transformers 29 and 30. An SBM 1A has pulse transformers 31 and 32 and the monitoring IC 15A. An SBM 1B has pulse transformers 33 and 34 and a monitoring IC 15B.

The microcomputer 24 and the monitoring IC 15A can perform communication via the communication IC 28, the pulse transformer 29, a communication line 35, and the pulse transformer 31. The microcomputer 24 and the monitoring IC 15B can perform communication via the communication IC 28, the pulse transformer 30, a communication line 36, and the pulse transformer 34. The monitoring ICs 15A and 15B can perform communication via the pulse transformer 32, a communication line 37, and the pulse transformer 33.

<Communication between Microcomputer and Battery Monitoring Device>

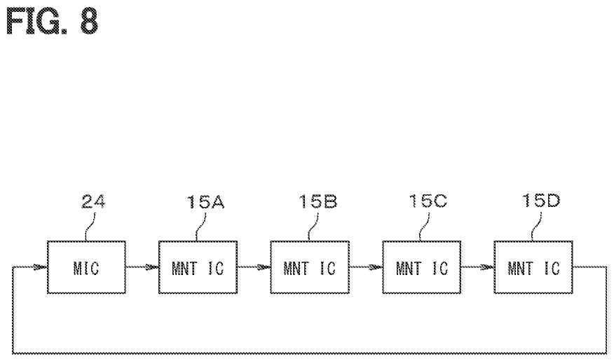

Subsequently, outline of communication between the microcomputer 24 and each of the monitoring ICs 15 will be described with reference to FIG. 8. It is assumed that the number of monitoring ICs 15 is four. The four monitoring ICs 15 are distinguished from one another by designating “A”, “B”, “C”, and “D” to the ends of the reference numerals.

In communication with the monitoring IC 15A, the microcomputer 24 transmits data including a write command instructing execution of a process such as voltage detection or diagnosis to the monitoring IC 15A. Such data including the write command is sequentially transmitted from the monitoring IC 15A to the monitoring IC 15D by daisy chain communication. Consequently, by transmitting the data including the write command to one monitoring IC 15A, the microcomputer 24 can instruct execution of a process such as voltage detection or diagnosis to all of the monitoring ICs 15.

In communication with the monitoring IC 15A, the microcomputer 24 transmits data including a read command requesting reading of a result of a process such as voltage detection or diagnosis to the monitoring IC 15A. Data including such a read command and a result of the process read in the target monitoring IC 15 is sequentially transmitted from the monitoring IC 15A to the monitoring IC 15D by daisy chain communication. As described above, by transmitting the data including the read command to one monitoring IC 15A, the microcomputer 24 can obtain the results of the processes such as voltage detection or diagnosis performed by all of the monitoring ICs 15.

### <General Configuration of Monitoring IC>

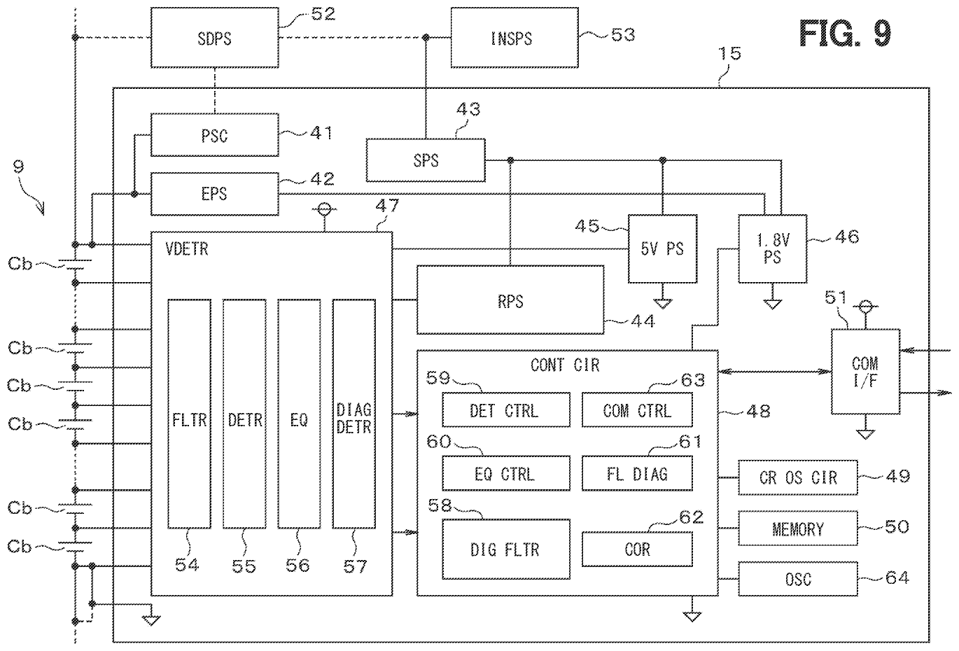

As a specific general configuration of the monitoring IC 15, for example, a configuration illustrated in FIG. 9 can be employed. As illustrated in FIG. 9, the monitoring IC 15 has a power source controller (PSC) 41, an equalization power source (EPS) 42, a simplified power source (SPS) 43, a reference power source (RPS) 44, a 5V power source (5V PS) 45, a 1.8V power source (1.8V PS) 46, a voltage detector (VDETR) 47, a control circuit (CONT CIR) 48, a CR oscillation circuit (CR OS CIR) 49, a memory 50, a communication I/F (COM I/F) 51, and the like.

The power source IC 15 has three operation modes; a normal mode of executing a normal operation, a dark current mode in which all of operations are stopped, and an equalization mode of executing an equalizing process. The dark current mode is a mode when power supply to the monitoring IC 15 is interrupted, that is, a mode when the power source is off. To the monitoring IC 15, as its power source for operation, either an output of a step-down power source (SDPS) 52 and an output of an insulating power source (INSPS) 53 is selectively input. The step-down power source 52 is a step-down-type switching power source or the like and generates an operation power for the monitoring IC 15 by stepping down the voltage of the battery module 9 to be monitored. The insulating power source 53 generates an operation power for the monitoring IC 15 by using a +B power source of the vehicle. The monitoring IC 15 operates using the output of the insulating power source 53 as the operation power at the normal time and, in the case such that the output of the insulating power source 53 cannot be normally obtained, operates using the output of the step-down power source 52 as the operation power.

The power source controller 41 controls the operation of the step-down power source 52. Specifically, the power source controller 41 stops operation by turning off the switching element of the step-down power source 52 or the like at the normal time and, when the output of the insulating power source 53 cannot be obtained normally, executes an operation of generating power by the step-down power source 52. By stepping down the voltage of the battery module 9, the equalization power source 42 generates a power supplied to the 1.8V power source 46. The equalization power source 42 operates in a period in which the monitoring IC 15 is set in the equalization mode and stops the operation in the other modes; the normal mode, and the dark current mode.

The simplified power source 43 receives either the output of the step-down power source 52 or the output of the insulating power source 53 and steps down the output and eliminates noise, thereby generating a power supplied to the reference power source 44, the 5V power source 45, and the 1.8V power source 46. The reference power source 44 generates reference voltages which are used in the voltage detector 47. The 5V power source 45 generates a power supply voltage of the side of 5V used in the voltage detector 47 or the like.

The 1.8V power source 46 generates a power source voltage on the side of 1.8V used in the control circuit 48 and the like. The 1.8V power source 46 operates on either the output of the equalization power source 42 or the output of the simplified power source 43. Specifically, the 1.8V power source 46 operates on the output of the simplified power source 43 in a period in which the monitoring IC 15 is set in the normal mode and operates on the output of the equalization power source 42 in a period in which the monitoring IC 15 is set in the equalization mode.

To the voltage detector 47, the terminal voltage of each of the battery cells Cb constructing the battery module 9 is input. The voltage detector 47 has a filter (FLTR) 54, a detector (DETR) 55, an equalizer (EQ) 56, a diagnosing detector (DIAG DETR) 57, and the like. The filter 54 is a low-pass filter such as an RC filter, receives the voltage of each battery cell Cb, eliminates a low-frequency component, and outputs the resultant. In the present disclosure, a low-pass filter will be also abbreviated as an LPF.

The detector 55 has multiple ADCs provided for the battery cells Cb in a one-to-one corresponding manner, A/D converts an output of the filter 54, and outputs a digital signal obtained by the A/D conversion to the control circuit 48. The equalizer 56 is configured by multiple equalization switches for executing equalization. The diagnosing detector 57 has a multiplexer and an ADC, detects voltages of the multiple battery cells Cb in a time-division manner, and outputs a digital signal expressing the detection value to the control circuit 48.

The control circuit 48 is configured as a logic circuit and has, as its functional blocks, a digital filter (DIG FLTR) 58, a detection controller (DET CTRL) 59, an equalization controller (EQ CTRL) 60, a failure diagnostic unit (FL DIAG) 61, a corrector (COR) 62, and a communication controller (COM CTRL) 63. To the control circuit 48, the CR oscillation circuit 49 generating a clock signal, the memory 50 for storing various data, and an oscillator (OSC) 64 are connected. The control circuit 48 operates using a clock signal supplied from the CR oscillation circuit 49 as an operation clock.

The digital filter 58 functions as an LPF receiving a digital signal output from the detector 55 and eliminating a low-frequency component in the signal. The detection controller 59 controls the operation of the detector 55 and detects the voltage of the battery cell Cb based on the output signal of the digital filter 58, that is, executes the above-described voltage detection process. The equalization controller 60 controls the operation of the equalizer 56 and executes the above-described battery equalizing process.

The failure diagnostic unit 61 controls the operation of the diagnosing detector 57 and, based on a digital signal output from the diagnosing detector 57 and a result of voltage detection by the detection controller 59, diagnoses a failure in various paths, configurations, and the like related to the voltage detection, that is, executes the above-described failure diagnosis process. The correcting unit 62 executes various correcting processes which are necessary in various processes. The communication control unit 63 controls communication performed with an external device via the communication UF 51.

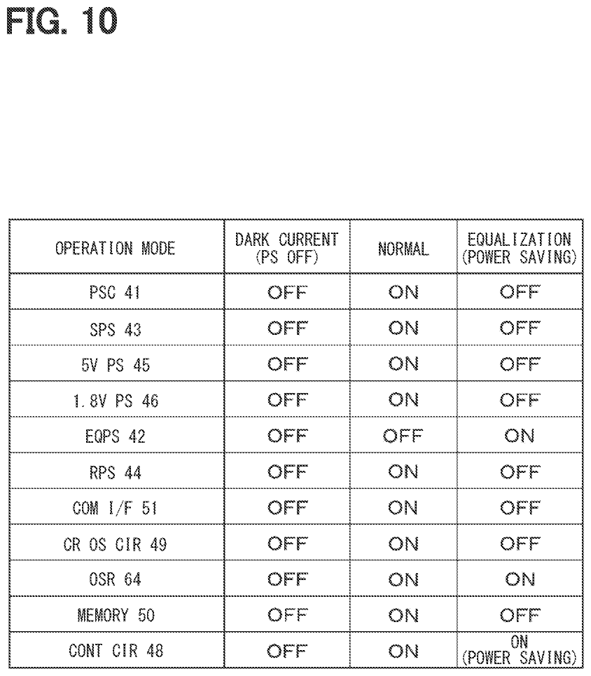

In the monitoring IC 15 having the above configuration, according to an operation mode which is set, the operation state of each of the components changes as illustrated in FIG. 10. In FIG. 10, for each component, a state in which the operation is executed is expressed as “ON”, and a state in which the operation is stopped is expressed as “OFF”. As illustrated in FIG. 10, when the monitoring IC 15 is set in the dark current mode, all of the components are turned off. Consequently, at the time of setting the dark current mode, the consumption current of the monitoring IC 15 becomes a value corresponding to the dark current.

When the monitoring IC 15 is set in the normal mode, the equalization power source 42 in the components is turned off, and the components other than the equalization power source 42 are turned on. Consequently, when the normal mode is set, the consumption current of the monitoring IC 15 becomes a steady-state value. When the monitoring IC 15 is set in the equalization mode, the equalization power source 42, the oscillator 64, and the control circuit 48 in the components are turned on and the other components are turned off.

In the case where the monitoring IC 15 is set in the equalization mode, since it is sufficient to execute only the battery equalizing process, as described above, the components which are not related to the equalization are turned off. In the process of the battery equalization, the operation flow is that a predetermined equalization switch is turned on, the on state is continued for a predetermined time and, after that, the equalization switch is turned off. The equalization controller 60 of the control circuit 48 measures the above-described predetermined time by using a clock signal supplied from the oscillator 64.

When the process of battery equalization is executed, although the control circuit 48 is turned on, the operation of the function blocks which are not related to equalization is unnecessary, so that only the function blocks which are related to equalization such as the equalization controller 60 are in the operation state. Due to this, in the equalization mode, the consumption current of the monitoring IC 15 becomes a value lower than the steady-state value. That is, the equalization mode becomes a power-saving mode as compared with the normal mode.

### <Specific Circuit Configuration of Main Part of Monitoring IC>

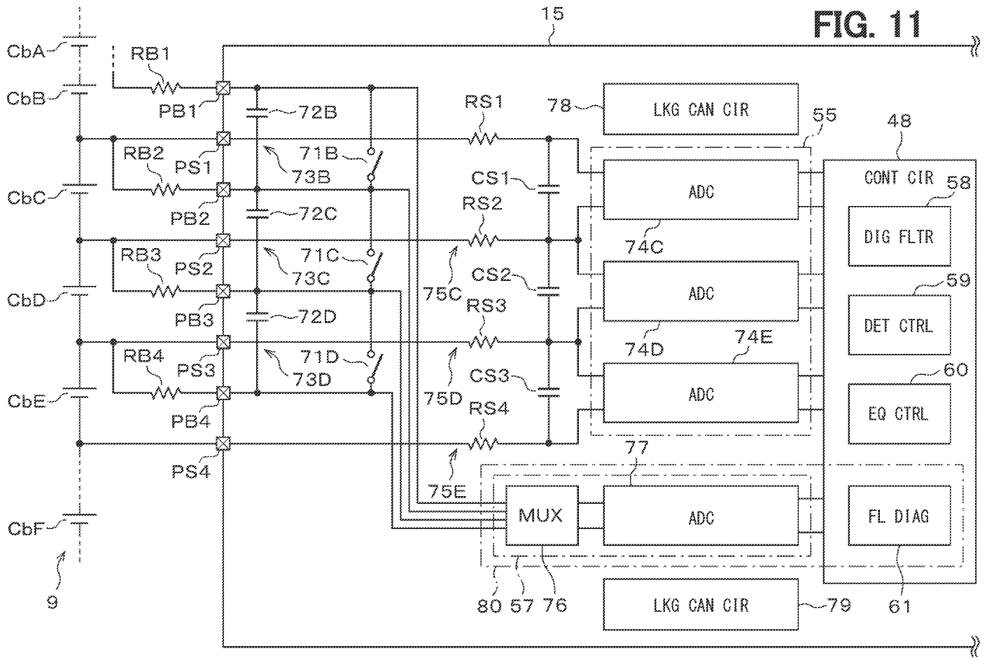

As a specific circuit configuration of a main part of the monitoring IC 15, for example, a configuration as illustrated in FIG. 11 can be employed. In FIG. 11, six battery cells Cb out of multiple battery cells Cb of the battery module 9 to be monitored of the monitoring IC 15 are illustrated, and “A” to “F” are designated at the ends of the reference numerals so that the six battery cells Cb are discriminated from one another.

Also to the components provided respectively to the six battery cells Cb, similar alphabets are designated to the ends of the reference numerals, so that the components are discriminated from one another. When it is unnecessary to discriminate the components from one another, the alphabets at the ends are omitted and the components are generally called. Although components corresponding to, mainly, three battery cells CbC, CbD, and CbE are illustrated with respect to the monitoring IC 15 in FIG. 11, the components corresponding to the other battery cells Cb are also similar.

The battery cell CbA is disposed on the highest potential side in the battery module 9, and the battery cell CbF is disposed on the lowest potential side in the battery module 9. The battery cells CbB to CbE are disposed in arbitrary positions between the battery cells CbA and CbF in the battery module 9. The high-potential-side terminal of the battery cell CbB and the low-potential-side terminal of the battery cell CbA adjacent on the high-potential side of the battery cell CbB are connected to a connection terminal PB1 via an equalization resistor RB1.

The low-potential-side terminal of the battery cell CbB and the high-potential-side terminal of the battery cell CbC are connected to a connection terminal PS1 and also connected to a connection terminal PB2 via an equalization resistor RB2. The low-potential-side terminal of the battery cell CbC and the high-potential-side of the battery cell CbD are connected to a connection terminal PS2 and also connected to a connection terminal PB3 via an equalization resistor RB3. The low-potential-side terminal of the battery cell CbD and the high-potential-side terminal of the battery cell CbE are connected to a connection terminal PS3 and also connected to a connection terminal PB4 via an equalization resistor RB4. The low-potential-side terminal of the battery cell CbE and the high-potential-side of a not-illustrated battery cell Cb adjacent to the low potential side of the battery cell CbF are connected to a connection terminal PS4.

Between the connection terminals PB1 and PB2, an equalization switch 71B and a capacitor 72B are connected in parallel. Between the connection terminals PB2 and

PB3, an equalization switch 71C and the capacitor 72B are connected in parallel. Between the connection terminals PB3 and PB4, the equalization switch 71B and the capacitor 72B are connected in parallel. An equalization switch 71 is configured by, for example, an N-channel-type MOSFET and its on/off is controlled by the equalization controller 60 of the control circuit 48. The equalization switch 71 and a capacitor 72 are included in the above-described equalizer 56.

In this case, by the equalization resistors RB1 to RB4 and the capacitor 72, an RC filter of a pi-shape is configured. Specifically, the capacitor 72B forms an RC filter 73B in cooperation with the equalization resistors RB1 and RB2. A capacitor 72C forms an RC filter 73C in cooperation with the equalization resistors RB2 and RB3. A capacitor 72D forms an RC filter 73D in cooperation with the equalization resistors RB3 and RB4.

In the above configuration, the RC filter 73B functions as an LPF which receives terminal voltages of the battery cells CbB given via the connection terminals PB1 and PB2 and eliminates a low-frequency component in the voltages. The RC filter 73C functions as an LPF which receives terminal voltages of the battery cell CbC given via the connection terminals PB2 and PB3 and eliminates a low-frequency component in the voltages. The RC filter 73D functions as an LPF which receives terminal voltages of the battery cell CbD given via the connection terminals PB3 and PB4 and eliminates a low-frequency component in the voltages.

One of the terminals of a resistor RS1 is connected to the connection terminal PS1, and the other terminal is connected to one of input terminals of an A/D converter (ADC) 74C. One of the terminals of a resistor RS2 is connected to the connection terminal PS2, and the other terminal is connected to the other input terminal of the ADC 74C. A capacitor CS1 is connected between the other terminal of the resistor RS1 and the other terminal of the resistor RS2. By the resistors RS1 and RS2 and the capacitor CS1, an RC filter 75C of a pi shape is configured.

The other terminal of the resistor RS2 is also connected to one of the input terminals of an ADC 74. One of terminals of a resistor RS3 is connected to the connection terminal PS3, and the other terminal is connected to the other input terminal of the ADC 74D. A capacitor CS2 is connected between the other terminal of the resistor RS2 and the other terminal of the resistor RS3. An RC filter 75D of a pi shape is configured by the resistors RS2 and RS3 and the capacitor CS2.

The other terminal of the resistor RS3 is connected also to one of the input terminals of an ADC 74E. One of terminals of the resistor RS4 is connected to the connection terminal PS4, and the other terminal is connected to the other input terminal of the ADC 74E. A capacitor CS3 is connected between the other terminal of the resistor RS3 and the other terminal of the resistor RS4. An RC filter 75E of a pi shape is configured by the resistors RS3 and RS4 and the capacitor CS3.

In the above configuration, the RC filter 75C functions as an LPF which receives terminal voltages of the battery cells CbC given via the connection terminals PS1 and PS2 and eliminates a low-frequency component in the voltages. The RC filter 75D functions as an LPF which receives terminal voltages of the battery cell CbD given via the connection terminals PS2 and PS3 and eliminates a low-frequency component in the voltages. The RC filter 75E functions as an LPF which receives terminal voltages of the battery cell CbE given via the connection terminals PS3 and PS4 and eliminates a low-frequency component in the voltages. As the details will be described later, the RC filter 75 functions as an anti-alias filter which controls aliasing by the digital filter 58 of the control circuit 48.

To the ADC 74C, an output voltage of the RC filter 75C, that is, an input voltage according to the voltage of the corresponding battery cell CbC is input. The ADC 74C A/D converts such an input voltage and outputs a digital signal obtained as a result of the conversion to the control circuit 48. To the ADC 74D, an output voltage of the RC filter 75D, that is, an input voltage according to the voltage of the corresponding battery cell CbD is input. The ADC 74D A/D converts such an input voltage and outputs a digital signal obtained as a result of the conversion to the control circuit 48.

To the ADC 74E, an output voltage of the RC filter 75E, that is, an input voltage according to the voltage of the corresponding battery cell CbE is input. The ADC 74E A/D converts such an input voltage and outputs a digital signal obtained as a result of the conversion to the control circuit 48. The operation of the ADC 74 is controlled by the detection controller 59 of the control circuit 48.

As described above, the monitoring IC 15 has multiple ADCs 74 provided in correspondence with the multiple battery cells Cb, respectively, and receiving input voltages according to the voltages of the corresponding battery cells Cb. In this case, the ADC 74 also performs level-shift which decreases high common voltage to low common voltage. As the ADC 74, for example, an ADC of a system of relatively high conversion accuracy such as a ΣΔ-type ADC can be employed.

In the above configuration, to the ADC 74, an input voltage is input via a detection path connected to both terminals of the corresponding battery cell Cb. Specifically, the detection paths corresponding to the ADC 74C are a path “the high-potential-side terminal of the battery cell CbC→the connection terminal PS1→the resistor RS1→the ADC 74C” and a path “the low-potential-side terminal of the battery cell CbC→the connection terminal PS2→the resistor RS2→the ADC 74C”.

The detection paths corresponding to the ADC 74D are a path “the high-potential-side terminal of the battery cell CbD→the connection terminal PS2→the resistor RS2→the ADC 74D” and a path “the low-potential-side terminal of the battery cell CbD→the connection terminal PS3→the resistor RS3→the ADC 74D”. The detection paths corresponding to the ADC 74E are a path “the high-potential-side terminal of the battery cell CbE→the connection terminal PS3→the resistor RS3→the ADC 74E” and a path “the low-potential-side terminal of the battery cell CbE→the connection terminal PS4→the resistor RS4→the ADC 74E”.

In the above configuration, the equalization switch 71 has a configuration capable of discharging the corresponding battery cell Cb via an equalization path different from the above-described detection path. Specifically, equalization paths corresponding to the equalization switch 71B are a path “the high-potential-side terminal of the battery cell CbB→the resistor RBI→the connection terminal PB1→the equalization switch 71B” and a path “the low-potential-side terminal of the battery cell CbB→the resistor RB2→the connection terminal PB2→the equalization switch 71B”.

Equalization paths corresponding to the equalization switch 71C are a path “the high-potential-side terminal of the battery cell CbC→the resistor RB2→the connection terminal PB2→the equalization switch 71C” and a path “the low-potential-side terminal of the battery cell CbC→the resistor RB3→the connection terminal PB3→the equalization switch 71C”. Equalization paths corresponding to the equalization switch 71D is a path “the high-potential-side terminal of the battery cell CbD→the resistor RB3→the connection terminal PB3→the equalization switch 71D” and a path “the low-potential-side terminal of the battery cell CbD→the resistor RB4→the connection terminal PB4→the equalization switch 71D”.

The diagnosing detector 57 has a multiplexer (MUX) 76 and an ADC 77. To the multiplexer 76, output voltages of the RC filter 73, that is, input voltages according to the voltages of the battery cells Cb are input. In other words, to the multiplexer 76, input voltages according to the voltages of the battery cells Cb are input via the above-described equalization paths. The multiplexer 76 selects any one of the input voltages and outputs it to the ADC 77.

The ADC 77 A/D converts the input voltage given from the multiplexer 76 and outputs a digital signal obtained as a result of the conversion to the control circuit 48. In this case, as the ADC 77, ADCs of various types such as a ΣΔ-type ADC can be employed. The operations of the multiplexer 76 and the ADC 77 are controlled by the equalization controller 60 of the control circuit 48.

A leakage cancelling circuit (LKG CAN CIR) 78 reduces leakage current flowing via a path for inputting an input voltage according to the voltage of the high-potential-side terminal of the battery cell CbA, that is, an output voltage on the high-potential side output from the RC filter 75 provided in correspondence with the battery cell CbA to the ADC 74. A leakage cancelling circuit 79 reduces leakage current flowing via a path for inputting an input voltage according to the voltage of the low-potential-side terminal of the battery cell CbF, that is, an output voltage on the low potential side output from the RC filter 75 provided in correspondence with the battery cell CbF to the ADC 74.

Since the leakage current here is similar to leakage current described in JP 2017-156194 A, its description is omitted, and JP 2017-156194 A will be referred to as necessary. As a specific configuration of the leakage cancelling circuits 78 and 79, for example, each of the configurations disclosed in JP 2017-156194 A can be employed. The operation of the leakage cancelling circuits 78 and 79 is controlled by the control circuit 48.

The digital filter 58 of the control circuit 48 functions as an LPF which receives a digital signal output from the ADC 74 and eliminates a low-frequency component in the signal. The cut-off frequency of the digital filter 58 can be set to an arbitrary value. The detection controller 59 of the control circuit 48 controls the operation of the ADCs 74 and detects the voltage of each of the battery cells Cb based on an output signal of the digital filter 58. In this case, the detection controller 59 controls the operation of the ADCs 74 so that multiple input voltages are A/D converted at the same timing. The “same timing” in the present disclosure and the like includes not only the case that timings match perfectly but also the case that timings are slightly different and, strictly, do not match as long as a target effect is produced. In this case, the detection controller 59 controls the operations of the ADCs 74 so that they always execute the converting operation.

The equalization controller 60 controls the operation of the equalizer 56, specifically, on/off operation of the equalization switch 71 and executes the above-described battery equalizing process. The failure diagnostic unit 61 controls the operation of the diagnosing detector 57 and, based on a digital signal output from the diagnosing detector 57 and a result of voltage detection by the detection controller 59, executes a process of failure diagnosis such as diagnosis of a failure related to the detection paths and the ADCs 74.

In this case, the failure diagnostic unit 61 compares a digital signal corresponding to a voltage detection value of the predetermined battery cell Cb output from the ADC 74 and a digital signal corresponding to a voltage detection value of a predetermined battery cell Cb output from the diagnosing detector 57. Specifically, when the digital signals, that is, the detection values match, the failure diagnostic unit 61 diagnoses that both of the detection path corresponding to a predetermined battery cell Cb and the ADC 74 are normal. When the detection values are different, the failure diagnostic unit 61 diagnoses that a failure occurs in at least one of the detection path corresponding to the predetermined battery cell Cb and the ADC 74.

In the above configuration, by the diagnosing detector 57 and the failure diagnostic unit 61, a failure diagnosing circuit 80 detecting voltages of multiple battery cells Cb via the equalization path and, based on the detection value, diagnosing a failure related to the detection path and the ADC 74 is configured. In this case, the failure diagnosing circuit 80 has the diagnosing detector 57 functioning as one voltage detecting circuit detecting voltages of the battery cells Cb in a time division manner.

### <Characteristics of RC Filter and Digital Filter>

In the above configuration, the RC filter 75 has, not a single-type configuration dedicated to each of the battery cells Cb, but a non-single-type configuration that a resistor as a circuit element constructing a filter are shared by the adjacent battery cells Cb. One of reasons of employing such a configuration is that the non-single-type filter has an advantage that an amount of resistance to common-mode noise improves as compared with the single-type filter. The non-single-type filter has, however, the following demerits. Specifically, in the case of a single-type filter, the constant of the filter, that is, a time constant of the filter is not subject to the influence of another filter, so that the constant values of the filters can be set to values which are almost the same. That is, no filter constant deviation occurs.

On the other hand, in the case of the RC filter 75 as a non-single-type filter, the constant of each of the RC filters 75 is subject to the influence of not only a circuit element as a component of itself but also a circuit element as a component of another RC filter 75. Consequently, the constant of each of the RC filters 75 varies depending on the position in the battery module 9 of the battery cell Cb corresponding to the RC filter 75. Therefore, in this case, it is difficult to set the constants of the RC filter 75 to the same value. That is, a filter constant deviation occurs.

To solve such a problem, in the present embodiment, the digital filter 58 is provided in addition to the RC filter 75, and the cut-off frequency of the digital filter 58 is set to a value lower than the cut-off frequency of the RC filter 75. The cut-off frequency of the RC filter 75 becomes a value which varies among the RC filters 75, accompanying the filter constant variations which occur as described above. In the present embodiment, in consideration of such a point as well, the cut-off frequency of the digital filter 58 is set to be lower than the cut-off frequencies of all of the RC filters 75. The cut-off frequency of the digital filter 58 is set to a value at which cell noise as noise superimposing on the battery cell Cb can be sufficiently eliminated.

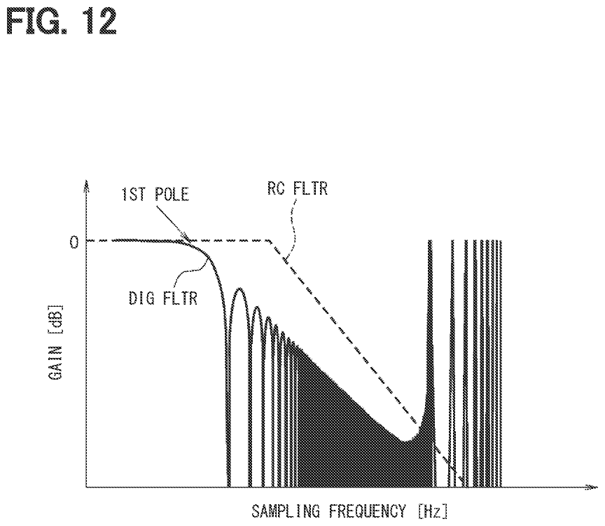

The characteristics of the entire filter exerting an influence on the result of detection of the voltage of the battery cell Cb in the monitoring IC 15 having the above configuration are as illustrated in FIG. 12. In FIG. 12, the characteristic of the digital filter (DIG FLTR) 58 is indicated by the solid line, and the characteristic of the RC filter (RC FLTR) 75 is indicated by the dotted line. As illustrated in FIG. 12, a first pole of the cut-off frequency of the entire filter depends on the cut-off frequency of the digital filter 58.

Consequently, in the above configuration, the cell noise is eliminated by the digital filter 58 and elimination of the RC filter 75 hardly contributes. In the digital filter 58, however, there is aliasing as illustrated in FIG. 12. In this case, the cut-off frequency of the RC filter 75 is set to a value at which the aliasing of the digital filter 58 can be reduced. Although the cut-off frequency of the RC filter 75 becomes a varied value as described above, it is easy to set the cut-off frequencies of all of the RC filters 75 to a range to a degree that such aliasing can be suppressed.

### <Specific Configuration of ADC>

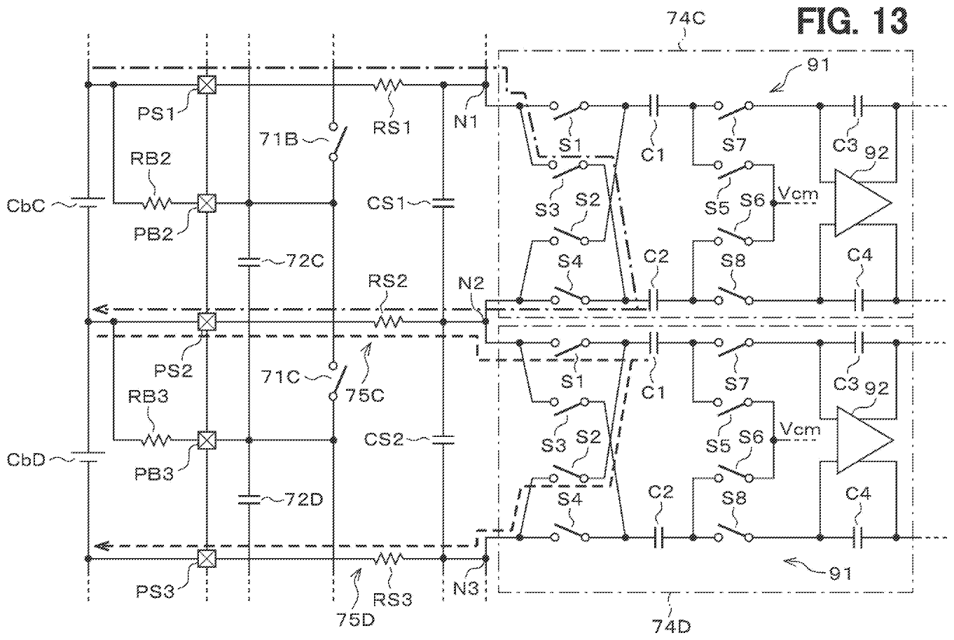

As a specific configuration of the ADC 74, for example, a configuration as illustrated in FIG. 13 can be employed. Although the configuration of the ADC 74 will be described using the configuration of the ADC 74C illustrated as an example, the illustrated ADC 74D and not-illustrated other ADCs 74 have a similar configuration. The ADC 74 is a ΣΔ-type ADC and has a switched capacitor circuit 91 of a differential configuration of detecting the difference voltage between two nodes N1 and N2 to which the above-described input voltage is applied and an OP amplifier 92 of a differential output form. In FIG. 13, illustration of the configuration of a part of the configuration of the ADC 74 is omitted.

A capacitor C3 is connected between one of input terminals and one of output terminals of the OP amplifier 92, and a capacitor C4 is connected between the other input terminal and the other output terminal of the OP amplifier 92. The capacitors C3 and C4 function as integral capacity. The differential voltage output from the output terminals of the OP amplifier 92 is supplied to the control circuit 48. The common voltage of the OP amplifier 92 is set equal to a voltage Vcm. The voltage Vcm is an intermediate voltage of two reference voltages used in the ADC 74.

The switched capacitor circuit 91 has switches S1 to S8 and capacitors C1 to C4. The capacitors C1 and C2 paired in the differential configuration are provided for charging the input voltage and have capacity values which are the same. The “same capacity value” in the present disclosure includes not only capacity values which match perfectly but also capacity values which are slightly different and, strictly, do not match as long as a target effect is produced.

One of the terminals of the capacitor C1 is connected to the node N1 via the switch S1 and also connected to the node N2 via the switch S2. One of the terminals of the capacitor C2 is connected to the node N1 via the switch S3 and also connected to the node N2 via the switch S4. To each of the other terminals of the capacitors C1 and C2, the voltage Vcm can be applied via the switches S5 and S6, respectively. The other terminals of the capacitors C1 and C2 are connected to the input terminals of the OP amplifier 92 via the switches S7 and S8, respectively.

The switches S1 to S8 are configured by semiconductor switching elements such as, for example, MOSFETs and their on/off states are controlled by the detection controller 59 of the control circuit 48. When the switches S1, S4, S5, and S6 are generally called a first switch and the switches S2, S3, S7, and S8 are generally called a second switch, the first and second switches are turned on/off complementarily. Specifically, the first switch is turned on in a sample period in which sampling operation of charging the capacitors C1 and C2 is performed in the switched capacitor circuit 91. The second switch is turned on in a hold period in which holding operation of holding charges accumulated in the capacitors C1 and C2 is performed in the switched capacitor circuit 91.

In the above configuration, the ADCs 74C and 74D share a path for inputting an input voltage according to the voltage of the low-potential-side terminal of the battery cell CbC and a path for inputting an input voltage according to the voltage of the high-potential-side terminal of the battery cell CbD. That is, in the present embodiment, two ADCs 74 provided in correspondence with the two adjacent battery cells Cb share a path for inputting an input voltage according to the voltage of the low-potential-side terminal of one of the two battery cells Cb and a path for inputting an input voltage according to the voltage of the high-potential-side terminal of the other one of the two battery cells.

In such a configuration, the leakage current is reduced, that is, the leak cancelling can be performed as follows. In one cycle of the operation in the switched capacitor circuit 91 of the ADC 74C, discharge current which discharges the capacitor 2 flows. The discharge current flows, as illustrated by the thick alternate long and short dash line in FIG. 13, in a path of “the high-potential-side terminal of the battery cell CbC→the connection terminal PS1→the resistor RS1→the switch S3→the switch S4→the resistor RS2→the connection terminal PS2→the low-potential-side terminal of the battery cell CbC”.

In one cycle of the operation in the switched capacitor circuit 91 of the ADC 75D, charge current which charges the capacitor Cl flows. The charge current flows, as illustrated by the thick dotted line in FIG. 13, in a path of “the high-potential-side terminal of the battery cell CbD→the connection terminal PS2→the resistor RS2→the switch S1→the switch S2→the resistor RS3→the connection terminal PS3→the low-potential-side terminal of the battery cell CbD”.

In such a manner, in the above configuration, the above-described charge current and discharge current flow in the paths shared by the ADCs 74C and 74D. In this case, the potentials of the adjacent two battery cells CbC and CbD, specifically, the potential of the low-potential-side terminal of the battery cell CbC and the potential of the high-potential-side terminal of the battery cell CbD become almost the same. Consequently, the charge current and the discharge current are in directions opposite to each other and have current values of the same degree. Therefore, the leakage current hardly flows in the path shared by the ADCs 74C and 74D and, as a result, the leak cancelling is realized.

### <Chip Configuration of Monitoring IC>

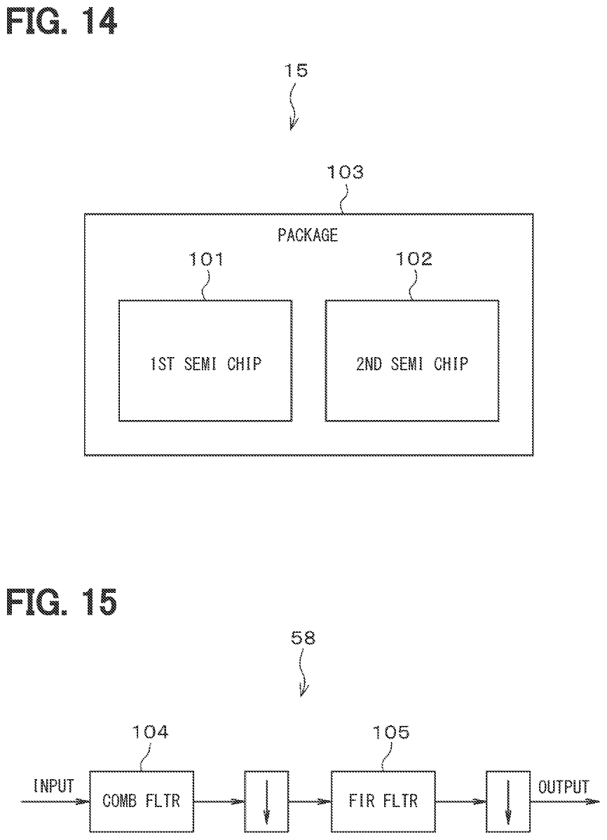

As the chip configuration of the monitoring IC 15, for example, a configuration as illustrated in FIG. 14 can be employed. As illustrated in FIG. 14, the monitoring IC 15 is an IC of a multi-chip package that multiple semiconductor chips are housed in one package. Specifically, the monitoring IC 15 has a first semiconductor chip (1ST SEMI CHIP) 101, a second semiconductor chip (2ND SEMI CHIP) 102, and a package 103 housing the first semiconductor chip 101 and the second semiconductor chip 102.

Each of the first and second semiconductor chips 101 and 102 is a plate-shaped semiconductor chip made of semiconductor such as silicon. In the first semiconductor chip 101, the RC filter 75 is formed. The resistors RS1 to RS4 and the like constructing the RC filter 75 are formed by, for example, polysilicon resistors, thin-film resistors, or the like. Each of the capacitors CS1 to CS3 and the like constructing the RC filter 75 is formed by, for example, integrating a trench capacitor configured by forming a trench in a semiconductor substrate and forming an electrode and a derivative.

In the second semiconductor chip 102, a circuit such as the control circuit 48 having the ADC 74, the digital filter 58, and the detection controller 59 is formed. As described above, in the monitoring IC 15, the RC filter 75 is configured as an IC together with the ADC 74, the digital filter 58, and the detection controller 59. The monitoring IC 15 is, for example, mounted on a not-illustrated circuit board together with the components having the battery monitoring function such as the equalization resistors RB1 to RB4, that is, other circuit elements which are not mounted in the monitoring IC 15 in the circuit elements constructing the battery monitoring unit 1. The resistors RS1 to RS4 and the like constructing the RC filter 75 may be provided as external parts on the outside of the monitoring IC 15.

### <Specific Configuration of Digital Filter>

The ΣΔ-type ADC is based on the oversampling method and realizes A/D conversion of high resolution by performing sampling at frequency sufficiently higher than the signal band, performing noise shaping by a ΣΔ modulator, and eliminating quantization noise driven to the high frequency by the digital filter 58. Consequently, in the case of employing a ΣΔ-type ADC as the ADC 74, the digital filter 58 has to be an LPF capable of passing only signal components sufficiently lower than the sampling frequency from a signal subject to the oversampling and eliminating the other quantization noise, that is, having a very low cut-off frequency.

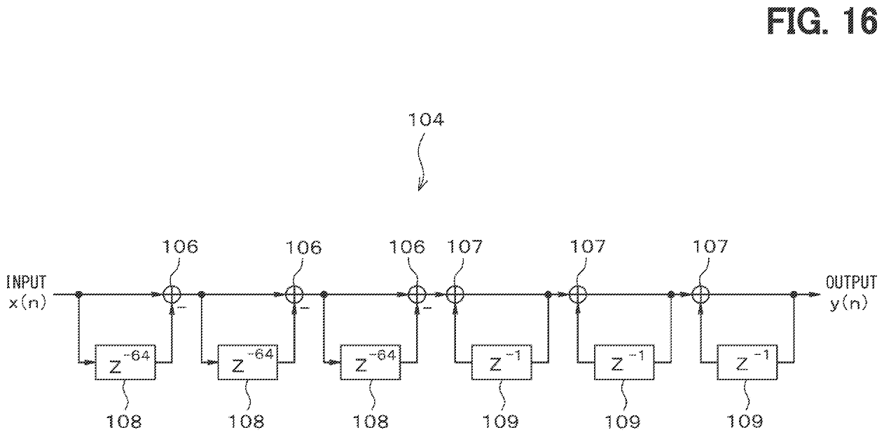

It is difficult to realize such a digital filter 58 by a digital filter of one stage for reasons such that the order of a filter has to be set extremely high and accuracy of a filter coefficient has to be made high. As a specific configuration of the digital filter 58, for example, a configuration as illustrated in FIG. 15 can be employed. The digital filter 58 illustrated in FIG. 15 has two functions of low-pass filtering and decimation. Decimation is an operation of lowering the sampling frequency by decimating a sample value from over-sampled signals at predetermined intervals.

At the time of decimation, it is necessary to consider that components other than the signal band are not converted to the signal band by aliasing and mixed in the signal band. It is also necessary to consider that the order of the filter does not become unnecessarily high. In the configuration of FIG. 15, those points are solved. That is, in this case, a signal output from the ADC 74 first passes through a comb-shaped filter (COMB FLTR) 104 as a digital low-pass filter having a simple configuration. It decreases the quantization noise to a certain degree.

After that, in the above configuration, decimation of the first stage is performed. In FIG. 15, blocks in which the decimation is performed are expressed by downward arrows. In the above configuration, by passing an output after the decimation at the first stage an FIR-type digital filter (FIR FLTR) 105, the quantization noise other than the necessary signal band is attenuated. By the noise component which resides after that, the signal-to-noise ratio, that is, SNR of the ADC 74 is determined. FIR is abbreviation of Finite Impulse Response.

After that, in the above configuration, decimation at the second stage is performed, and the sampling frequency is decreased to the frequency which is the bare minimum for the signal bandwidth. Since the comb-shaped filter 104 has zero points periodically, after the decimation at the first stage, an aliasing component of the quantization noise can be prevented from being mixed in the signal band. Therefore, the characteristic of the digital filter does not have to be steep. After that, the noise outside the signal band is eliminated by the digital filter 105 of the FIR type having a steep cut-off characteristic. Since the sampling frequency is already made low by the decimation of the first stage, it is unnecessary to make the cut-off frequency extremely lower than the sampling frequency, and a request for steepness of the cut-off frequency is also lessened.

The comb-shaped filter 104 is also called an averaging filter and has a configuration of outputting a value obtained by simply adding some consecutive sample values. As a specific configuration of the comb-shaped filter 104, for example, a configuration as illustrated in FIG. 16 can be employed. The comb-shaped filter 104 illustrated in FIG. 16 has multiple adders 106 and 107 and multiple delay devices 108 and 109 provided between an input x(n) and an output y(n) and is a comb-shaped filter of three degree of N=64. Such a configuration has, for example, an attenuation characteristic larger as compared with a comb-shaped filter of one stage, so that it is suitable to be employed in the digital filter 58 receiving an output of a ΣΔ-type ADC.

According to the present embodiment described above, the following effects can be obtained. The monitoring IC 15 has multiple ADCs 74 respectively provided in correspondence with the battery cells Cb, the control circuit 48, and the like. The control circuit 48 has the digital filter 58 receiving a digital signal output from the ADC 74 and functioning as an LPF and the detection controller 59 controlling the operation of the ADCs 74 and detecting the voltage of the battery cell Cb based on an output signal of the digital filter 58.

The detection controller 59 controls the operation of the ADCs 74 so that multiple input voltages are A/D converted at the same timing. By the operation, the detection controller 59 can detect the voltage of each of the battery cells Cb based on a digital signal obtained by the A/D conversion performed by the ADCs 74 at the same timing. Consequently, by the above configuration, the detection timings of the voltages of the battery cells Cb can be set to the same, that is, synchronousness of the detection timings of the voltages of the battery cells Cb can be increased.

In the above configuration, cell noise is eliminated by the digital filter 58. Generally, aliasing occurs in a digital filter. In the above configuration, the RC filter 75 functioning as an anti-aliasing filter for suppressing occurrence of such aliasing is provided. As described above, in the above configuration, cell noise can be eliminated without providing a differential amplification circuit at the stage before each of the ADCs 74, so that various errors caused by the differential amplification circuit do not occur. Therefore, by the monitoring IC 15 of the present embodiment, excellent effects are obtained such that synchronousness of the detection timings of the voltages of the battery cells Cb can be increased and the voltage detection accuracy can be increased.

In this case, the cut-off frequency of the digital filter 58 is set to a value at which cell noise can be sufficiently eliminated and a value lower than the cut-off frequency of the RC filter 75. Due to this, in the above configuration, the cut-off frequency for cell noise elimination depends on the cut-off frequency of the digital filter 58. Consequently, it is sufficient that the cut-off frequency of the RC filter 75 is a value at which aliasing by the digital filter 58 can be reduced and, even the value varies to a certain extent, there is no problem. Therefore, in the above configuration, the configuration of the RC filter 75 can be simplified.

Specifically, in the above configuration, the RC filter 75 can employ the filter configuration of the non-single type, not the filter configuration of the single type. As described above, in the case of a filter of the non-single type, filter constant deviation occurs. However, in this case, there is no problem when the constant of the RC filter 75, that is, the cut-off frequency varies to a certain extent. In the filter of the non-single type, as compared with the filter of the single type, a part of circuit elements constructing the filter is shared by the adjacent battery cells Cb, so that the configuration can be simplified by that amount. Therefore, by the above configuration, the circuit area of the battery monitoring IC 15 can be suppressed to be small.

Generally, the cut-off frequency of the digital filter can be changed relatively easily. Consequently, by the above configuration, the cut-off frequency for cell noise elimination can be easily changed according to the setting of the cut-off frequency of the digital filter 58. Therefore, by the above configuration, for example, according to the destination of the monitoring IC 15, without changing the configuration of the RC filter 75 or the like, the cut-off frequency for cell noise elimination can be individually set.

In this case, the RC filter 75 has the configuration of a pi filter. In the configuration of the pi filter, the RC filters 75 are connected to the ground via the capacitors 72 constructing them. Consequently, by such a configuration, common mode noise superimposed on the battery cell Cb can be also suppressed.

In the present embodiment, the RC filter 75 is constructed as the monitoring IC 15 as a semiconductor device together with the ADCs 74 and the control circuit 48 including the digital filter 58 and the detection controller 59. Specifically, the monitoring IC 15 has the configuration of a multi-chip package including the first semiconductor chip 101 in which the RC filter 75 is formed, the second semiconductor chip 102 in which the ADC 74, the control circuit 48, and the like are formed, and one package 103 housing the first and second semiconductor chips 101 and 102.

By integrating the RC filter 75 in the monitoring IC 15, external parts of the monitoring IC 15 are reduced. Consequently, the area of the circuit board for mounting various elements including the monitoring IC 15 constructing the battery monitoring unit 1 can be suppressed to be small, that is, miniaturization of the circuit board can be realized. In this case, since the monitoring IC 15 has the configuration of the multi-chip package, the area of the circuit board can be further suppressed only by the amount.

The monitoring IC 15 can execute the process of battery equalization and has the equalization switch 71 provided in correspondence with each of the multiple battery cells Cb, for discharging the corresponding battery cell Cb. In this case, input voltage is applied to the ADC 74 via the detection path connected to both terminals of the corresponding battery cell Cb, and the equalization switch 71 discharges the corresponding battery cell Cb via an equalization path different from the detection path.

By such a configuration, the following effects are obtained. Specifically, in the above detection path, the RC filter 75 is interposed and, as described above, constant deviation occurs in each of the RC filters 75. In this case, the equalization path is a path different from the detection path and is not influenced by the RC filter 75. Therefore, by the above configuration, when the battery equalization process is executed, without being subject to the influence of constant deviation of the RC filter 75, the target battery cell Cb can be properly discharged and, as a result, the accuracy of the battery equalization can be made excellent.

In the present embodiment, the ADCs 74 always perform operation of A/D converting the input voltage. Due to this, it becomes difficult to diagnose a failure related to the detection path and the like by using the ADCs 74 because the configuration of claim 7 is employed. In the above-described manner, a failure related to the detection path and the like can be diagnosed.

In the present embodiment, each of the ADCs 74 performs the converting operation consecutively, that is, always performs the converting operation. Consequently, it is difficult to diagnose a failure related to the detection path or the like by using the ADCs 74 during the operation. Particularly, since the ΣΔ-type ADCs are employed as the ADCs 74 in the present embodiment, such diagnosis is more difficult. The reason is that, in the ΣΔ-type ADCs, when the converting operation is stopped in the middle, relatively long time is needed at the time of starting the operation again. Due to this, the operation such that the ADCs 74 stop the converting operation in the middle, failure diagnosis is performed by using them and, after that, the converting operation is restarted is not realistic.

Consequently, in the present embodiment, the monitoring IC 15 is provided with the diagnosing detector 57 which detects voltages of the multiple battery cells Cb via the equalization path and the failure diagnostic unit 61 diagnosing a failure related to the detection path and the ADCs 74 based on the detection value by the diagnosing detector 57. In such a manner, also in the configuration of the present embodiment that the ADC 74 always performs the converting operation, a failure related to the detection path and the like can be diagnosed.

At the time of failure diagnosis, synchronousness of the detection timings of voltages of the battery cells Cb is not important. Therefore, the diagnosing detector 57 has the multiplexer 76 and one ADC 77 and detects voltages of the multiple battery cells Cb in a time division manner. In such a manner, as compared with the configuration that an ADC as a voltage detection circuit for diagnosis is provided for each of the battery cells Cb, the configuration of the diagnosing detector 57 can be simplified, and the circuit area of the monitoring IC 15 as a whole can be suppressed to be small.

In this case, the equalization path is provided with the RC filter 73 having the configuration of a pi filter similar to the RC filter 75. In this case, in the equalization path used for detecting the voltage of the battery cell Cb at the time of failure diagnosis, the RC filter 73 having a configuration similar to that of the RC filter 75 interposed in the detection path used to detect the voltage of the battery cell Cb at the time of voltage detection is interposed. With such a configuration, since a mode that a detection value obtained via the detection path on a predetermined battery cell Cb and a detection value obtained via the equalization path are similar is obtained, an effect that the accuracy of failure diagnosis executed by using the detection values improves is obtained.

In the present embodiment, each of the ADCs 74 has the switched capacitor circuit 91 of the differential configuration detecting the difference voltage between two input nodes to which the input voltage is applied. The two ADCs 74 provided in correspondence with the adjacent two battery cells Cb share the path for inputting the input voltage according to the voltage of the low-potential-side terminal of one of the two battery cells Cb and the path for inputting the input voltage according to the voltage of the high-potential-side terminal of the other one of the two battery cells Cb. In such a configuration, as described above, occurrence of leakage current which can occur accompanying the operation of the voltage detection in the shared paths is largely reduced.

However, even in the above configuration, since the supply of the paths as described above becomes impossible in the path for inputting the input voltage according to the voltage of the high-potential-side terminal of the battery cell CbA disposed on the highest-potential side in the battery module 9 and the path for inputting the input voltage according to the voltage of the low-potential-side terminal of the battery cell CbF disposed on the lowest-potential side in the battery module 9, there is the possibility that leakage current occurs via those paths. In the present embodiment, the leakage cancelling circuits 78 and 79 are provided to reduce the leakage current flowing through the paths. In such a manner, leakage current which may occur accompanying the operation of the voltage detection can be reliably reduced.

### Second Embodiment

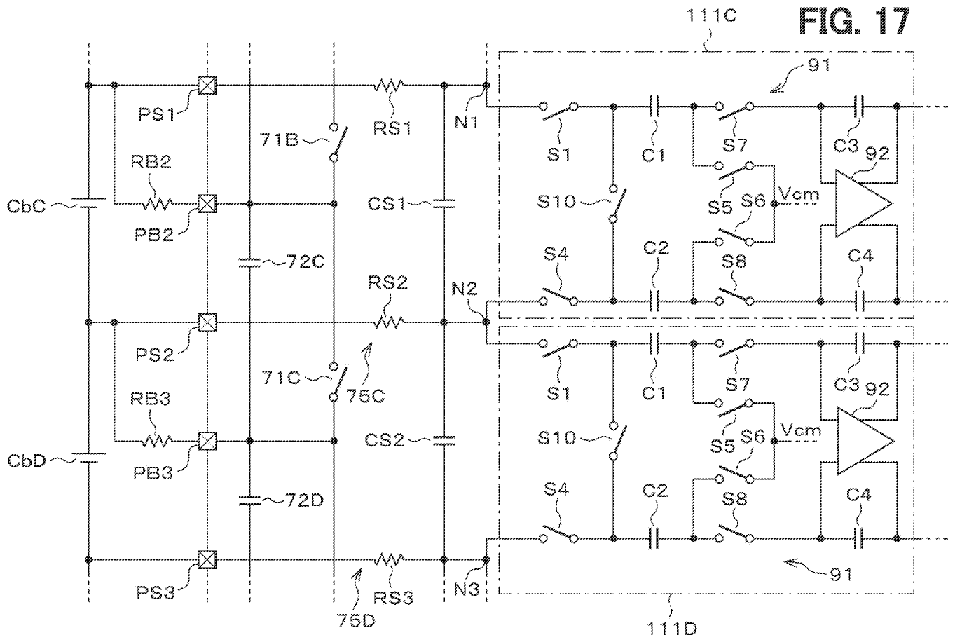

Hereinafter, a second embodiment will be described with reference to FIG. 17.

As a specific configuration of the ADCs provided in correspondence with the battery cells Cb, respectively, the present disclosure is not limited to the specific configuration described in the first embodiment but can employ various configurations. In the second embodiment, another specific configuration example of the ADC will be described.

As illustrated in FIG. 17, ADCs 111C and 111D of the present embodiment are different from the ADCs 74C and 74D illustrated in FIG. 13 with respect to the point such that a switch S10 is provided in place of the switches S2 and S3. In this case, the switch S10 is turned on/off at timings similar to those of the switches S2 and S3.

Also by the ADC 111 of the present embodiment described above, operation similar to that of the ADC 74 of the first embodiment can be performed. Therefore, also by the second embodiment, effects similar to those of the first embodiment can be obtained. According to the second embodiment, the number of switches constructing the ADC 111 can be decreased by one as compared with the ADC 74 of the first embodiment, and an effect that the circuit area can be reduced by that amount is obtained.

### Third Embodiment

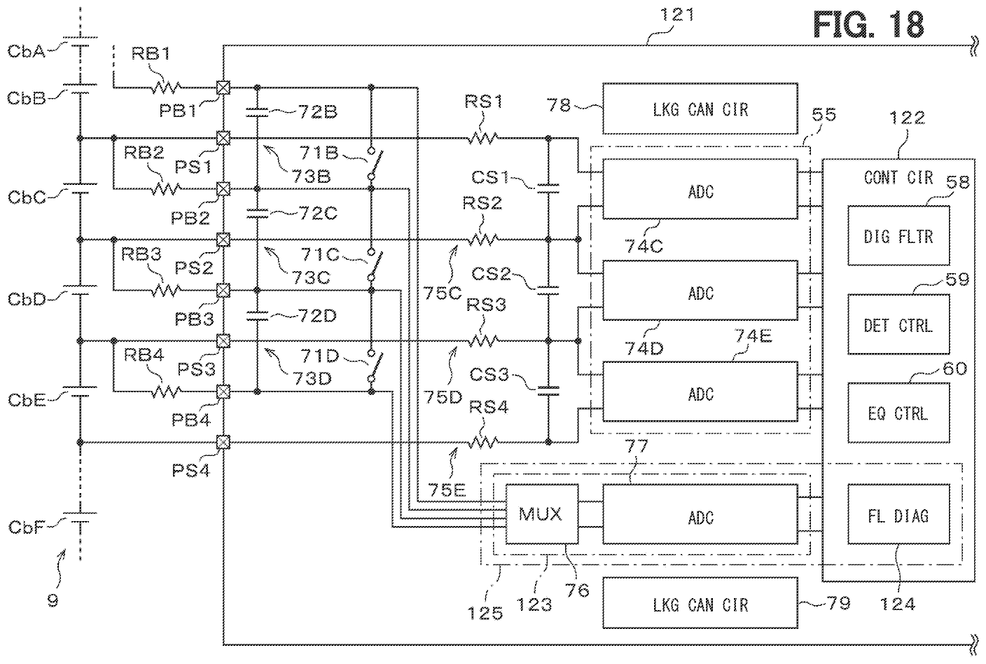

Hereinafter, a third embodiment in which a specific circuit configuration of the main part of the monitoring IC of the first embodiment is changed will be described with reference to FIGS. 18 to 21.

As illustrated in FIG. 18, a monitoring IC 121 of the third embodiment is different from the monitoring IC 15 of the first embodiment with respect to the points such that a control circuit (CONT CIR) 122 is provided in place of the control circuit 48, and a diagnosing detector 123 is provided in place of the diagnosing detector 57.

The control circuit 122 is different from the control circuit 48 with respect to the point such that a failure diagnostic unit (FL DIAG) 124 is provided in place of the failure diagnostic unit 61. In the configuration, by the diagnosing detector 123 and the failure diagnostic unit 124, a failure diagnosing circuit 125 detecting the voltages of the battery cells Cb via the equalization path and, based on the detection value, diagnosing a failure related to the detection path and the ADC 74 is configured. In this case, the failure diagnosing circuit 125 has the diagnosing detector 123 functioning as one voltage detection circuit detecting the voltages of the multiple battery cells Cb in a time division manner. As described above in the first embodiment, in the equalization path, the RC filter 73 having a configuration similar to that of the RC filter 75 interposed in the detection path is interposed. In this case, the RC filter 73 has a configuration having the same pole, that is, the same cut-off frequency as that of the RC filter 75.

The failure diagnosing circuit 125 controls the detection timing of the voltage of the battery cell Cb by the diagnosing detector 123 so that at least a part of a period in which the voltage of the battery cell Cb is detected by the diagnosing detector 123 overlaps a period in which the voltage of the battery cell Cb is detected by the detection controller 59. Specifically, the failure diagnosing circuit 125 controls the detection timing of the voltage of the battery cell Cb by the diagnosing detector 123 so that the period in which the voltage of a predetermined battery cell Cb is detected by the diagnosing detector 123 and the period in which the voltage of the predetermined battery cell Cb is detected by the detection controller 59 overlap. That is, in the present embodiment, with respect to the predetermined battery cell Cb, the voltage detection by the diagnosing detector 123 and the voltage detection by the detection controller 59 are performed at the same time.

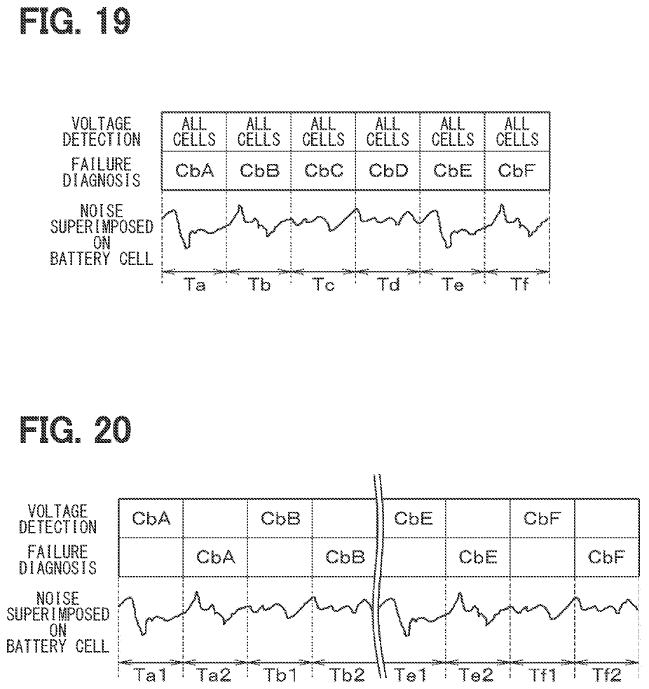

As described above, the present embodiment is characterized by the detection timing of the voltage of the battery cell Cb by the diagnosing detector 123. Hereinafter, a specific example of such a detecting timing will be described with reference to FIG. 19. In the following description, detection of the voltage of the battery cell Cb for the voltage detecting process by the detection controller 59 will be called voltage detection for the voltage detecting process, and detection of the voltage of the battery cell Cb for the failure diagnosing process by the diagnosing detector 123 will be called voltage detection for the failure diagnosing process. In FIG. 19 and the like, the voltage detection for the voltage detecting process will be shortly written as “voltage detection” and the voltage detection for the failure diagnosing process will be shortly written as “failure diagnosis”.

As illustrated in FIG. 19, in a specific example of the detection timing of the present embodiment, in a manner similar to the first embodiment, the voltage detections for the voltage detecting process for all of the battery cells Cb are performed at the same timing. That is, in this case, the voltage detection for the voltage detecting process is executed at the same time for all of the cells. In this case, the voltage detection for the failure diagnosing process for the battery cells Cb is performed as the same timing as that of the voltage detection for the voltage detecting process executed at the same time for all of the cells.

Specifically, in a period Ta, the voltage detection for the voltage detecting process for all of the battery cells Cb is performed, and the voltage detection for the failure diagnosing process for the battery cell CbA are performed. Consequently, in the period Ta, for the same battery cell CbA, the voltage detection for the voltage detecting process and the voltage detection for the failure diagnosing process are executed at the same time, that is, in parallel. In a period Tb, the voltage detection for the voltage detecting process for all of the battery cells Cb is performed and the voltage detection for the failure diagnosing process for the battery cells CbB is performed. Consequently, in the period Tb, the voltage detection for the voltage detecting process and the voltage detection for the failure diagnosing process are performed for the same battery cell CbB in parallel.

In a period Tc, the voltage detection for the voltage detecting process for all of the battery cells Cb and also the voltage detection for the failure diagnosing process for the battery cell CbC are performed. Consequently, in the period Tc, the voltage detection for the voltage detecting process and the voltage detection for the failure diagnosing process are performed in parallel for the same battery cell CbC. In a period Td, the voltage detection for the voltage detecting process for all of the battery cells Cb is performed and also the voltage detection for the failure diagnosing process for the battery cell CbD is performed. Consequently, in the period Td, the voltage detection for the voltage detecting process and the voltage detection for the failure diagnosing process are performed in parallel for the same battery cell CbD.

In a period Te, the voltage detection for the voltage detecting process for all of the battery cells Cb and also the voltage detection for the failure diagnosing process for the battery cell CbE are performed. Consequently, in the period Te, the voltage detection for the voltage detecting process and the voltage detection for the failure diagnosing process are performed in parallel for the same battery cell CbE. In a period Tf, the voltage detection for the voltage detecting process for all of the battery cells Cb is performed and also the voltage detection for the failure diagnosing process for the battery cell CbF is performed. Consequently, in the period Tf, the voltage detection for the voltage detecting process and the voltage detection for the failure diagnosing process are performed in parallel for the same battery cell CbF.

In a conventional monitoring IC, it is general to employ the detection timings so that the voltage detection for the voltage detecting process and the voltage detection for the failure diagnosing process are performed alternately, specifically, the detection timings as illustrated in FIG. 20 for the predetermined battery cell Cb. In the following, such a conventional detecting timing will be called a comparison example. In the comparison example, in the period Ta1, the voltage detection for the voltage detecting process for the battery cell CbA is performed. In the period Ta2, the voltage detection for the failure diagnosing process for the battery cell CbA is performed. That is, in the comparison example, the voltage detection for the voltage detecting process for the battery cell CbA and the voltage detection for the failure diagnosing process for the same battery cell CbA are alternately performed. With respect to the other battery cells CbB to CbF, similarly, the voltage detection for the voltage detecting process and the voltage detection for the failure diagnosing process are performed alternately.

In such a comparison example, since the detection timing of the voltage detection for the voltage detecting process and that of the voltage detection for the failure diagnosing process are different from each other, the detections are performed in noise environments different from each other. FIG. 20 and the like schematically illustrate an example of noise waveforms superimposed on the battery cell Cb. As an example of such noise waveforms, in many cases, the mode of noise superimposed on the battery cell Cb in the period Ta1 in which the voltage detection for the voltage detecting process for the predetermined battery cell CbA is performed and that in the period Ta2 in which the voltage detection for the failure diagnosing process for the same battery cell CbA is performed are different from each other.

In such a comparison example, the detection value of the voltage detection for the voltage detecting process for the predetermined battery cell Cb and the detection value of the voltage detection for the failure diagnosing process do not become similar and, as a result, there is the possibility that the accuracy of the failure diagnosis executed by using the detection values decreases. In the comparison example, since the voltage detection for the voltage detecting process and the voltage detection for the failure diagnosing process are performed in order for each battery cell Cb, there is a problem such that time required until the voltage detecting process corresponding to all of the battery cells Cb is completed becomes longer.

On the contrary, in the present embodiment, the voltage detection for the voltage detecting process and the voltage detection for the failure diagnosing process for the predetermined battery cell Cb are performed in parallel at the same timing. Consequently, in the present embodiment, as illustrated in FIG. 19, the voltage detection for the voltage detecting process for the predetermined battery cell CbA and the voltage detection for the failure diagnosing process for the same battery cell CbA are performed in the same period Ta, so that the modes of noise superimposed on the battery cell Cb when the detections are performed become the same, and detection in the same noise environment can be realized. Therefore, in the present embodiment, since the detection value of the voltage detection for the voltage detecting process and that of the voltage detection for the failure diagnosing process become similar to each other, an effect that the accuracy of failure diagnosis executed by using the detection values improves is obtained.

Further, in the present embodiment, the RC filter 75 interposed in the detection path and the RC filter 73 interposed in the equalization path have similar configurations, specifically, the same cut-off frequency. That is, the RC filter 75 interposed in the detection path and the RC filter 73 interposed in the equalization path are RC filters having the same pole. Consequently, in the present embodiment, the voltage detection for the voltage detecting process and the voltage detection for the failure diagnosing process can be made more in the same noise environment and, as a result, the accuracy of failure diagnosis can be further improved.

In the present embodiment, although the voltage detection for the failure diagnosing process is performed every battery cell Cb, the voltage detection for the voltage detecting process is performed to all of cells at the same time. Consequently, an effect is obtained such that, as compared with the comparison example, the total time until the voltage detecting process and the failure diagnosing process corresponding to all of the battery cells Cb are completed can be largely shortened. As described above, according to the present embodiment, the voltage detection for the voltage detecting process is performed to all of cells at the same time, so that the voltage detecting process can be completed in time of the reciprocal of the number of battery cells Cb to be detected as compared with the comparison example.

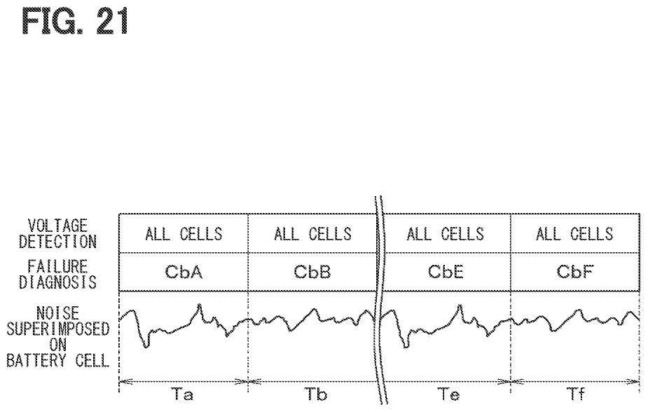

A modification of changing the cut-off frequency of the RC filters 73 and 75 to a lower frequency by using the effect of shortening of the time required for the voltage detecting process can be employed. According to such a modification, the components of lower frequencies can be eliminated by using the RC filters 73 and 75, and the accuracy of the voltage detecting process and the failure diagnosing process can be further increased. Moreover, in this case, as illustrated in FIG. 21, although the length of the period Ta or the like as time required for the voltage detection for one voltage detecting process becomes longer than that of the period Ta or the like illustrated in FIG. 19, the total time until the voltage detecting process and the failure diagnosing process for all of the battery cells Cb are completed can be maintained at time similar to that in the comparison example.

### Fourth Embodiment

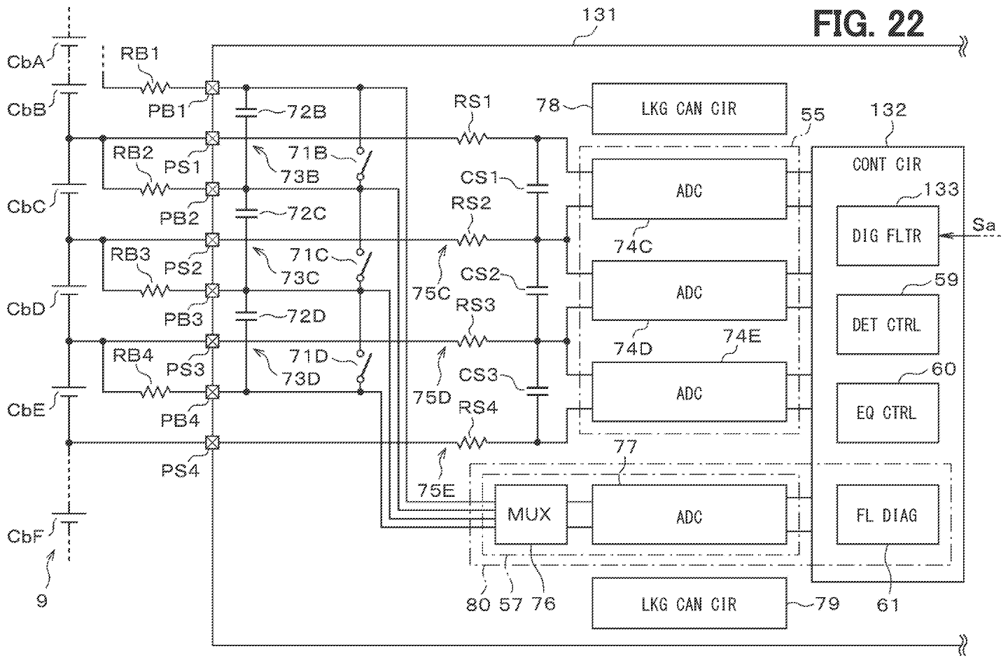

Hereinafter, a fourth embodiment will be described with reference to FIGS. 22 to 25. As illustrated in FIG. 22, a monitoring IC 131 of the present embodiment is different from the monitoring IC 15 of the first embodiment with respect to a point such that a control circuit 132 is provided in place of the control circuit 48. The control circuit 132 is different from the control circuit 48 with respect to a point such that a digital filter 133 is provided in place of the digital filter 58. The digital filter 133 functions as an LPF similar to the digital filter 58. The digital filter 133 has a configuration that the cut-off frequency can be changed based on a command signal Sa given from the outside. The command signal Sa is given from, for example, the main microcomputer 17.

In the configuration of the present embodiment described above, the following effects are obtained. That is, the cut-off frequency for cell noise elimination has to be set to an optimum value every kind of a vehicle in which the monitoring IC 131 is used, specifically, every maker of the vehicle, every vehicle kind, or the like. According to the configuration of the present embodiment, the cut-off frequency of the digital filter 133 exerting large influence on the cut-off frequency for cell noise elimination can be changed based on the command signal Sa.

Consequently, according to the configuration, the cut-off frequency for cell noise elimination can be easily switched based on the command signal Sa without accompanying a change in the hardware. For such a reason, the monitoring IC 131 of the present embodiment can be adapted to various different ECU systems by kinds of vehicles. Therefore, according to the present embodiment, although ECU design is conventionally necessary for each of vehicle systems, an excellent effect that the ECU configuration can be unified, that is, made common is obtained.

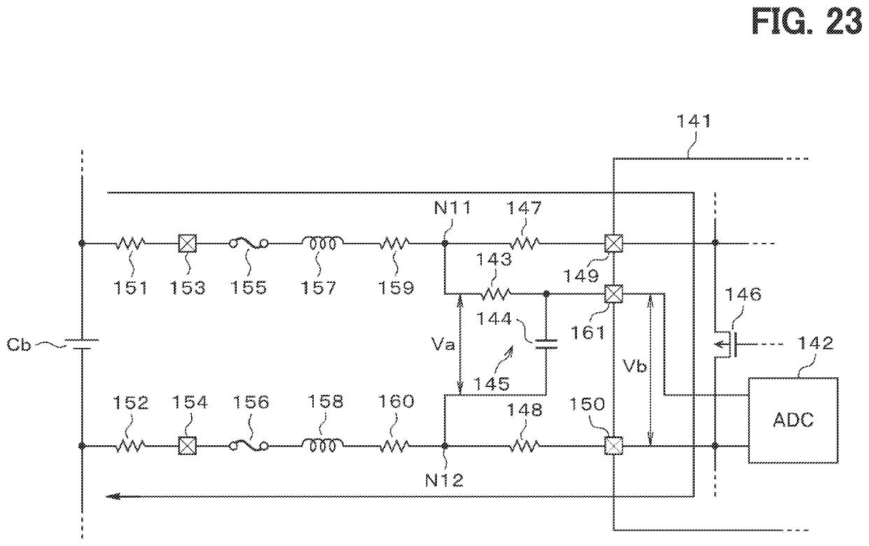

According to the configurations of the foregoing embodiments including the configuration of the fourth embodiment, that is, according to the configurations of the first to fourth embodiments, the following effects are obtained. Specifically, as illustrated in FIG. 23, in a conventional monitoring IC 141, a configuration that an RC filter 145 made by a resistor 143 and a capacitor 144 is externally provided to detect the voltage of the battery cell Cb by an ADC 142 with high accuracy is often employed. Hereinafter, such a conventional monitoring IC 141 will be called a comparison example. In the comparison example, by turning on an equalization switch 146, the battery cell Cb can be discharged by on resistance of equalization resistors 147 and 148 and the equalization switch 146.

In this case, the path from the high-potential-side terminal of the battery cell Cb to the low-potential-side terminal of the battery cell Cb via the equalization resistor 147, a connection terminal 149, the equalization switch 146, a connection terminal 150, and the equalization resistor 148 is an equalization path. In FIG. 23, the equalization path is indicated by the solid-line arrow. In the equalization path, in reality, as illustrated in FIG. 23, resistance components 151 and 152 of a harness connecting the battery cell Cb and the ECU, contact resistors 153 and 154 of a connector for connecting the harness, resistance components 155 and 156 of a fuse, resistance components 157 and 158 of ferrite beads, and wiring resistors 159 and 160 of the board exist.

In the configuration of the comparison example, a voltage Va between a node N11 as a mutual connection node of the wiring resistor 159 and the equalization resistor 147 and a node N12 as a mutual connection node of the wiring resistor 160 and the equalization resistor 148 corresponds to a cell voltage as the voltage of the battery cell Cb. In the configuration of the comparison example, the RC filter 145 is provided between the nodes N11 and N12 and the connection terminals 161 and 150, so that a delay occurs only by time according to the time constant of the RC filter 145, in the voltage Vb fed in the ADC 142 of the monitoring IC 141.

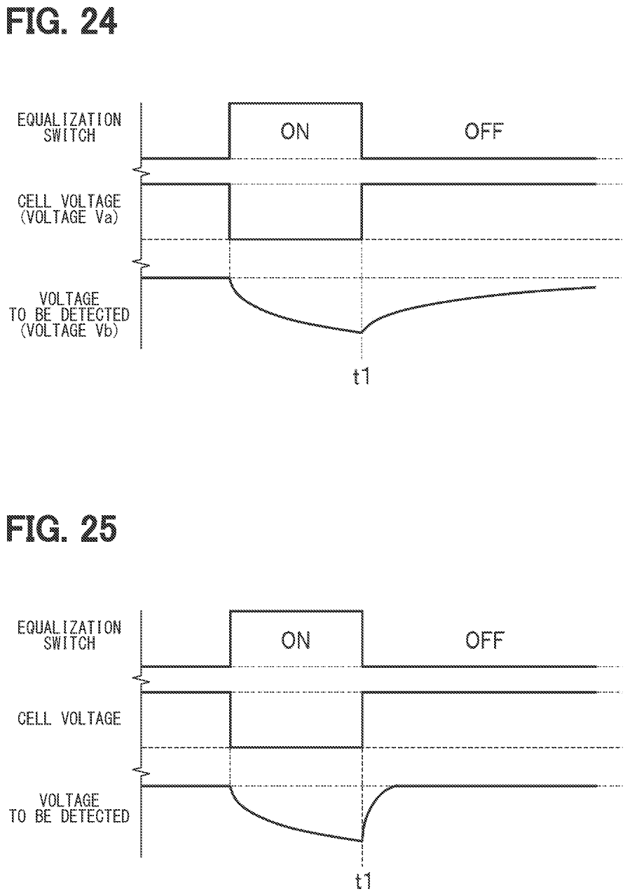

As illustrated in FIG. 24, at time point t1 when the equalization switch 146 turns from on to off, although the voltage Va rises steeply and becomes stable, the voltage Vb requires time according to the time constant of the RC filter 145 until it gently rises and becomes stable. Moreover, in the comparison example, the configuration of eliminating cell noise using only the RC filter 145 is employed, so that the cut-off frequency of the RC filter 145 has to be set to the low-frequency side and time required until the voltage Vb becomes stable becomes longer. Since the ADC 142 performs detecting operation after the voltage Vb becomes stable, in the comparison example, it becomes difficult to increase the speed of the system control to high speed.

On the contrary, in the configurations of the embodiments, since the main of the filters interposing in the detection paths are the digital filters 58 and 133, it is sufficient that the cut-off frequency of the RC filter 75 is a frequency to the degree capable of eliminating aliasing noise of the digital filters 58 and 133 and a frequency higher than that of the comparison example can be set. Consequently, in the configuration of each of the embodiments, as illustrated in FIG. 25, the voltage taken by the monitoring IC 131 or the like and detected rises steeply from the time point t1 when the equalization switch 71 changes from on to off and becomes stable more quickly as compared with the voltage Vb of the comparison example. As described above, in the configuration of each of the embodiments, time until the voltage detected after the equalization switch 71 changes from on to off becomes stable becomes time shorter than that in the comparison example and, as a result, the time required for the voltage detection is shortened, so that higher speed of the control can be realized.

### Other Embodiments

The present disclosure is not limited to the embodiments described above and illustrated in the drawings and can be arbitrarily modified, combined, or expanded without departing from the gist.

The numerical values and the like described in the foregoing embodiments are examples and the present disclosure is not limited to them.

An anti-alias filter for reducing aliasing of the digital filters 58 and 133 is not limited to the RC filter 75 described in the embodiments and, for example, filters of various configurations such as a pi LC filter can be employed.

The configuration of the failure diagnosing circuits 80 and 125 may not be limited to that described in each of the embodiments but can be properly changed as long as a similar function can be realized. For example, the failure diagnosing circuit may have multiple voltage detecting circuits detecting voltages of multiple battery cells Cb, respectively.

In each of the foregoing embodiments, the configuration of the multi-chip package is employed, in which the first semiconductor chip 101 in which the RC filter 75 is formed and the second semiconductor chip 102 in which the control circuit 48 and the like are formed are housed in one package 103. However, the configuration is not limited to the above. For example, a configuration that the first semiconductor chip 101 and the second semiconductor chip 102 are house in different packages, that is, a configuration that the RC filter 75 and the control circuit 48 are formed in two different ICs may be employed.

Although the present disclosure is described in accordance with the embodiments, it is to be understood that the present disclosure is not limited to the embodiments and structures. The present disclosure includes various modifications and also modifications in range of equivalency. In addition, although various combinations and modes, further, also other combinations and modes including only one element or more or less are within the range of the present disclosure and the idea range.

What is claimed is:

1. A battery monitoring device for monitoring an assembled battery in which a plurality of battery cells are connected in series, comprising:
a plurality of analog-to-digital (A/D) converters provided in correspondence with the plurality of battery cells, respectively, each of the plurality of A/D converters configured to receive an input voltage according to a voltage of corresponding one of the plurality of battery cells;
a digital filter configured to receive a digital signal output from each of the plurality of A/D converters and function as a low-pass filter;
an anti-alias filter configured to suppress aliasing by the digital filter; and
a detection controller configured to control operation of the plurality of A/D converters and detect the voltage of each of the plurality of battery cells based on an output signal of the digital filter, wherein
the detection controller controls the operation of the plurality of A/D converters so that the input voltage input to each of the plurality of A/D converters is A/D converted at a same timing, and
a cut-off frequency of the digital filter is set to a value lower than a cut-off frequency of the anti-alias filter.

2. The battery monitoring device according to claim 1, wherein
the anti-alias filter has a configuration of a pi filter.

3. The battery monitoring device according to claim 1, wherein
the anti-alias filter is configured as a semiconductor device, together with the plurality of A/D converters, the digital filter, and the detection controller.

4. The battery monitoring device according to claim 3, wherein
the semiconductor device includes:
a first semiconductor chip in which the anti-alias filter is disposed;
a second semiconductor chip in which the plurality of A/D converters, the digital filter, and the detection controller are disposed; and
one package housing the first semiconductor chip and the second semiconductor chip.

5. The battery monitoring device according to claim 1, further comprising
a plurality of equalization switches provided in correspondence with the plurality of battery cells, respectively, each of the plurality of equalization switches configured to discharge corresponding one of the plurality of battery cells, wherein
the input voltage is input to each of the plurality of A/D converters via a detection path connected to two terminals of the corresponding one of the plurality of battery cells, and
each of the plurality of equalization switches is configured to discharge the corresponding one of the plurality of battery cells via an equalization path different from the detection path.

6. The battery monitoring device according to claim 5, further comprising
a failure diagnosing circuit configured to detect the voltage of each of the plurality of battery cells via the equalization path and diagnose a failure related to the detection path and each of the plurality of A/D converters based on the voltage that is detected.

7. The battery monitoring device according to claim 6, wherein
the failure diagnosing circuit has one voltage detecting circuit configured to detect the voltage of each of the plurality of battery cells in a time division manner.

8. The battery monitoring device according to claim 7, wherein
the failure diagnosing circuit is configured to control a timing of detecting the voltage of each of the plurality of battery cells by the voltage detecting circuit in such a manner that at least a part of a period in which the voltage of each of the plurality of battery cells is detected by the voltage detecting circuit overlaps a period in which the voltage of each of the plurality of battery cells is detected by the detection controller.

9. The battery monitoring device according to claim 8, wherein
the equalization path has a filter having a configuration same as a configuration of the anti-alias filter.

10. The battery monitoring device according to claim 1, wherein
each of the plurality of A/D converters has a switched capacitor circuit having a differential configuration of detecting a differential voltage between two input nodes to which the input voltage is applied, and
two A/D converters in the plurality of A/D converters provided in correspondence with adjacent two battery cells in the plurality of battery cells share a path for inputting the input voltage according to a voltage of a low-potential-side terminal of one of the two battery cells and a path for inputting the input voltage according to a voltage of a high-potential-side terminal of another one of the two battery cells.

11. The battery monitoring device according to claim 8, further comprising
a leakage cancelling circuit configure to reduce a leakage current that flows via a path for inputting the input voltage according to the voltage of a high-potential-side terminal of one of the plurality of battery cells disposed on a highest potential side in the assembled battery and a leakage current that flows via a path for inputting the input voltage according to the voltage of a low-potential-side terminal of another one of the plurality of battery cells disposed on a lowest potential side in the assembled battery.

12. The battery monitoring device according to claim 1, wherein
the digital filter has a configuration capable of changing the cut-off frequency based on a command signal given from an outside.
